(19) United States
(12) Patent Application Publication
(10) Pub. No.: US 2026/0107638 A1
(43) Pub. Date: Apr. 16, 2026

(54) DISPLAY DEVICE AND ELECTRONIC DEVICE

(71) Applicant: Samsung Display Co., LTD., Yongin-si (KR)

(72) Inventors: Sun Kwun SON, Yongin-si (KR); Dong Hee SHIN, Yongin-si (KR); Na Hyeon CHA, Yongin-si (KR)

(21) Appl. No.: 19/265,780

(22) Filed: Jul. 10, 2025

(30) Foreign Application Priority Data
Oct. 10, 2024 (KR) 10-2024-0137392

(51) Int. Cl. H10K 59/122; H10K 59/38; H10K 59/80

(52) U.S. Cl. CPC H10K 59/122; H10K 59/38; H10K 59/80515; H10K 59/873

(57) ABSTRACT

The present disclosure relates to a display device and an electronic device. The display device includes a substrate, a thin film transistor on the substrate, a planarization layer on the thin film transistor, a protective layer on the planarization layer and having a plurality of recesses, a first electrode arranged corresponding to each of the plurality of recesses on the protective layer, a pixel definition layer defining a light emitting area and a non-light emitting area on the protective layer, an organic light emitting layer on the first electrode in the light emitting area, and a second electrode on the pixel definition layer and the organic light emitting layer. The first electrode is divided into a sloped portion on a sloped surface of the recess and a bottom portion at a lower end of the sloped portion, and the sloped portion may have a concave or convex pattern of unevenness.

### CROSS-REFERENCE TO RELATED APPLICATION

The present application claims priority to and the benefit of Korean Patent Application No. 10-2024-0137392, filed on Oct. 10, 2024, in the Korean Intellectual Property Office, the entire disclosure of which is incorporated herein by reference.

### BACKGROUND

### 1. Field

One or more embodiments of the present disclosure relate to a display device.

### 2. Description of the Related Art

As information society develops, the demand for display devices that display various information in the form of image is increasing rapidly. In response to this, one or more suitable types (kinds) of display devices, including light-emitting display devices, are being developed.

### SUMMARY

Aspects and features of embodiments of the present disclosure are directed toward a display device capable of improving the image quality of the display device by increasing the angle-specific luminance ratio (LvA) and minimizing or reducing the luminance ratio deviation (dLvA). Additional aspects and features will be set forth in part in the description which follows and, in part, will be apparent from the description, or may be learned by practice of the presented embodiments of the disclosure.

However, the present disclosure is not limited to those set forth herein. The above and additional embodiments of the present disclosure will become more apparent to one of ordinary skill in the art to which the present disclosure pertains by referencing the detailed description of the present disclosure given hereinafter.

According to one or more embodiments of the present disclosure, a display device includes a substrate, a thin film transistor on the substrate, a planarization layer on (e.g., arranged on) the thin film transistor, a protective layer on (e.g., arranged on) the planarization layer and having a plurality of recesses, a first electrode arranged corresponding to each of the plurality of recesses on the protective layer, a pixel definition layer defining a light emitting area and a non-light emitting area on the protective layer, an organic light emitting layer on (e.g., arranged on) the first electrode in the light emitting area, and a second electrode on (e.g., arranged on) the pixel definition layer and the organic light emitting layer, wherein the first electrode is divided into a sloped portion on (e.g., arranged on) a sloped surface of the recess and a bottom portion at (e.g., arranged at) a lower end of the sloped portion, and the sloped portion has a concave or convex pattern of unevenness.

According to one or more embodiments, the bottom portion may have a concave or convex pattern of unevenness.

According to one or more embodiments, the protective layer may have an uneven pattern on (e.g., arranged on) the sloped portion and the bottom portion.

According to one or more embodiments, a depth of the unevenness of the uneven pattern of the protective layer may be about 0.5 micrometers (μm) to about 1.0 μm, a width of the unevenness of the uneven pattern of the protective layer may be about 1.0 μm to about 2.0 μm, and a distance between the unevenness of the uneven pattern of the protective layer may be about 1.0 μm to about 2.0 μm.

According to one or more embodiments, the protective layer may include a first protective layer and a second protective layer on (e.g., arranged on) a top surface of the first protective layer, wherein an uneven pattern of the protective layer is formed on a top surface of the first protective layer and a bottom surface of the second protective layer.

According to one or more embodiments, the organic light emitting layer may be on (e.g., arranged on) the sloped portion and the bottom portion of the first electrode, wherein the organic light emitting layer includes an uneven pattern corresponding to an uneven pattern of the first electrode.

According to one or more embodiments, a thickness of the recess is formed to a depth smaller than a thickness of the protective layer, and the sloped surface of the recess is in a range of 20° to 70°. For example, a depth of the recess may be smaller than the thickness of the protective layer, and the sloped surface of the recess may have an inclination angle in a range of 20° to 70°.

According to one or more embodiments, the sloped portion of the first electrode may have substantially a same inclination angle as the sloped surface of the recess. For example, the sloped portion of the first electrode may have an inclination angle having (with) a substantially same measure (or measurement) as the inclination angle of the sloped surface of the recess.

According to one or more embodiments, the pixel definition layer may not overlap the sloped portion.

According to one or more embodiments, the protective layer includes a first protective layer and a second protective layer arranged on a top surface of the first protective layer, wherein an uneven pattern of the protective layer is formed on a top surface of the first protective layer and a bottom surface of the second protective layer.

According to one or more embodiments, the organic light emitting layer is arranged on the sloped portion and the bottom portion of the first electrode, wherein the organic light emitting layer includes an uneven pattern corresponding to an uneven pattern of the first electrode.

According to one or more embodiments, a thickness of the recess is formed to a depth smaller than a thickness of the protective layer, and wherein the sloped surface of the recess is in a range of 20° to 70°. For example, a depth of the recess is smaller than the thickness of the protective layer, and the sloped surface of the recess has an inclination angle in a range of 20° to 70°.

According to one or more embodiments, the sloped portion of the first electrode has a same inclination angle as the sloped surface of the recess. For example, the sloped portion of the first electrode has an inclination angle having (with) a same measure (or measurement) as the inclination angle of the sloped surface of the recess.

According to one or more embodiments, the pixel definition layer does not overlap the sloped portion.

According to one or more embodiments, the first electrode further includes a top portion on (e.g., arranged on) an upper end of the sloped portion, and wherein the pixel definition layer covers at least a portion of the top portion.

According to one or more embodiments of the present disclosure, a display device includes a substrate including a first light emitting area and a second light emitting area, a thin film transistor on the substrate, a planarization layer on (e.g., arranged on) the thin film transistor, a protective layer on (e.g., arranged on) the planarization layer and having a first recess and a second recess, respectively overlapping the first light emitting area and the second light emitting area, a first pixel electrode on (e.g., arranged on) the protective layer corresponding to the first recess and a second pixel electrode on (e.g., arranged on) the protective layer corresponding to the second recess, an organic light emitting layer including a first pixel light emitting layer on (e.g., arranged on) the first pixel electrode of the first light emitting area and a second pixel light emitting layer on (e.g., arranged on) the second pixel electrode of the second light emitting area, a pixel definition layer defining light emitting areas and non-light emitting areas on the protective layer, a common electrode on (e.g., arranged on) the pixel definition layer and the organic light emitting layer, wherein the second pixel electrode is divided into a sloped portion on (e.g., arranged on) a sloped surface of the second recess and a bottom portion at (e.g., arranged at) a lower end of the sloped portion, and the sloped portion and the bottom portion each have a concave or convex pattern of unevenness.

According to one or more embodiments, the first pixel electrode may be divided into a sloped portion on (e.g., arranged on) a sloped surface of the first recess and a bottom portion at (e.g., arranged at) a lower end of the sloped portion, and wherein the first pixel electrode does not include an uneven portion.

According to one or more embodiments, the first pixel electrode is divided into a sloped portion arranged on a sloped surface of the first recess and a bottom portion arranged at a lower end of the sloped portion, and wherein the first pixel electrode does not include an uneven portion.

According to one or more embodiments, the protective layer has an uneven pattern below (e.g., arranged below) the uneven patterns of the sloped portion and the bottom portion of the second pixel electrode.

According to one or more embodiments, a depth of the unevenness of the uneven pattern of the protective layer may be about 0.5 μm to about 1.0 μm, a width of the unevenness of the uneven pattern of the protective layer may be about 1.0 μm to about 2.0 μm, and a distance between the unevenness of the uneven pattern of the protective layer may be about 1.0 μm to about 2.0 μm.

According to one or more embodiments, the protective layer may include a first protective layer and a second protective layer on (e.g., arranged on) a top surface of the first protective layer, wherein the uneven pattern of the protective layer is formed on a top surface of the first protective layer and a bottom surface of the second protective layer.

According to one or more embodiments, a thickness of each of the first recess and the second recess is formed to a depth smaller than a thickness of the protective layer, and the sloped surface of each of the first recess and the second recess is in a range of 20° to 70°. For example, a depth of each of the first recess and the second recess is smaller than a thickness of the protective layer, and the sloped surface of each of the first recess and the second recess has an inclination angle in a range of 20° to 70°.

According to one or more embodiments, a sloped portion of the first pixel electrode has a same inclination angle as the sloped surface of the first recess, and the sloped portion of the second pixel electrode has a same inclination angle as the sloped surface of the second recess. For example, the sloped portion of the first pixel electrode may have an inclination angle having a substantially same measure (or measurement) as the inclination angle of the sloped surface of the first recess, and the sloped portion of the second pixel electrode may have an inclination angle having a substantially same measure (or measurement) as the inclination angle of the sloped surface of the second recess.

According to one or more embodiments, the display device may further include a thin film encapsulation layer on (e.g., arranged on) the common electrode and including a first inorganic film layer, a second inorganic film layer, and an organic film layer arranged between the first inorganic film layer and the second inorganic film layer, a color filter layer on the thin film encapsulation layer, and an overcoat layer between (e.g., arranged between) the thin film encapsulation layer and the color filter layer.

According to one or more embodiments, the color filter layer may include a first color filter overlapping the first light emitting area and a second color filter overlapping the second light emitting area, wherein the first color filter is one of a blue color filter that transmits blue light or a red color filter that transmits red light, and the second color filter is a green color filter that transmits green light.

According to one or more embodiments, a pattern of irregularities may be formed on the sloped portion of the second pixel electrode. As a result, the lateral luminance ratio and viewing angle of the pixel and the display device including the pixel may be improved. For example, the formation of these irregularities on the sloped portion of the second pixel electrode serves to scatter light more effectively, thereby enhancing the lateral luminance ratio. This scattering effect helps to distribute light more evenly across the viewing angles, reducing the intensity drop-off that typically occurs at wider angles. As a result, the viewing angle of the pixel and the display device is improved, providing a more consistent and high-quality image regardless of the observer's position.

However, the aspects, effects, and benefits of the present disclosure are not limited to the aforementioned aspects, effects, and benefits, and one or more other aspects, effects, and benefits are included in the present disclosure.

### BRIEF DESCRIPTION OF DRAWINGS

The accompanying drawings are included to provide a further understanding of the present disclosure and are incorporated in and constitute a part of the present disclosure. The drawings illustrate embodiments of the present disclosure and, together with the description, serve to explain principles of the present disclosure. The above and other aspects and features of the present disclosure will become more apparent and appreciated from the following descriptions of example embodiments thereof with reference to the accompanying drawings.

FIG. 1 is an exploded perspective view illustrating a display device according to one or more embodiments of the present disclosure.

FIG. 2 is a block diagram illustrating a display device according to one or more embodiments of the present disclosure.

FIG. 3 is an equivalent circuit diagram of a first sub-pixel according to one or more embodiments of the present disclosure.

FIG. 4 is a layout diagram illustrating an example of a display panel according to one or more embodiments of the present disclosure.

FIG. 5 is a layout diagram illustrating an example of a display area of FIG. 4 according to one or more embodiments of the present disclosure.

FIG. 6 is an enlarged view of a pixel according to one or more embodiments of the present disclosure.

FIG. 7 is a cross-sectional view illustrating an example of a display panel cut along the line I-I′ of FIG. 6 according to one or more embodiments of the present disclosure.

FIG. 8 may be an enlarged view of a via layer and a light emitting element in the light emitting area of FIG. 7 according to one or more embodiments of the present disclosure.

FIG. 9 is a cross-sectional view illustrating an example of a display panel cut along the line I-I′ of FIG. 6 according to one or more embodiments of the present disclosure.

FIG. 10 may be an enlarged view of a via layer and a light emitting element in the light emitting area of FIG. 9 according to one or more embodiments of the present disclosure.

FIG. 11 may be an enlarged view of a via layer and a light emitting element in the light emitting area of one or more embodiments of the present disclosure.

FIG. 12 is a table illustrating luminance ratio and luminance ratio deviation by angle relative to the square according to one or more embodiments of the present disclosure.

FIG. 13 is a cross-sectional view illustrating a display device including light emitting areas that emit light of different wavelengths according to one or more embodiments of the present disclosure.

FIG. 14 is a perspective view illustrating an example of a head mounted display according to one or more embodiments of the present disclosure.

FIG. 15 is an exploded perspective view illustrating the head mounted display device of FIG. 14 according to one or more embodiments of the present disclosure.

FIG. 16 is a perspective view showing an example of a head mounted display device according to one or more embodiments of the present disclosure.

### DETAILED DESCRIPTION

Aspects and features of embodiments of the present disclosure and methods of accomplishing the same may be understood more readily by reference to the detailed description of embodiments and the accompanying drawings. Hereinafter, aspects of one or more embodiments will be described in more detail with reference to the accompanying drawings. The described embodiments, however, may be embodied in one or more suitable different forms, and should not be construed as being limited to only the illustrated embodiments herein. Rather, these embodiments are provided as examples so that the present disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure might not be described for conciseness.

Unless otherwise noted, like reference numerals, characters, and/or one or more (e.g., any suitable) combinations thereof denote like elements throughout the attached drawings and the written description, and thus, duplicative descriptions thereof will not be repeated. Further, parts not related to the description of one or more embodiments might not be shown to make the description clear and conciseness.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, and/or the like, of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the present disclosure. Thus, embodiments disclosed herein should not be construed as limited to the particular illustrated shapes of regions, but are to include deviations in shapes that result from, for instance, manufacturing.

For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and thus are not intended to be limiting. Additionally, as those skilled in the art would realize, the described embodiments may be modified in one or more suitable different ways, all without departing from the spirit and/or scope of the present disclosure.

In the detailed description, for the purposes of explanation, numerous specific details are set forth to provide a thorough understanding of one or more suitable embodiments. It is apparent, however, that one or more suitable other embodiments may be practiced without these specific details or with one or more equivalent arrangements. In other instances, well-suitable structures and devices are shown in block diagram forms to avoid unnecessarily obscuring illustrated embodiments.

Spatially relative terms, such as “beneath,” “below,” “lower,” “under,” “above,” “upper,” and/or the like, may be used herein for ease of explanation to describe one element or feature's relationship to another element(s) or feature(s) as illustrated in the drawings. It will be understood that the spatially relative terms are intended to encompass different orientations of the device in use or in operation, in addition to the orientation depicted in the drawings. For example, if a device in the drawings is turned over, for example, upside down, elements described as “below” or “beneath” or “under” other elements or features would then be oriented “above” the other elements or features. Thus, the example terms “below” and “under” may encompass both (e.g., simultaneously) an orientation of above and below. In one or more embodiments, the device may be otherwise oriented (e.g., rotated 90 degrees or at other orientations) and the spatially relative descriptors used herein should be interpreted accordingly. Similarly, if (e.g., when) a first part is described as being arranged “on” a second part, this indicates that the first part is arranged at an upper side or a lower side of the second part without the limitation to the upper side thereof on the basis of the gravity direction.

Further, in the disclosure, the phrase “on a plane,” or “in a plan view,” refers to viewing a target portion from the top, and the phrase “on a cross-section” refers to viewing a cross-section formed by vertically cutting a target portion from a side.

It will be understood that if (e.g., when) an element, layer, region, or component is referred to as being “formed on,” “on,” “connected to,” or “coupled to” another element, layer, region, or component, it may be directly formed on, on, connected to, or coupled to the other element, layer, region, or component, or indirectly formed on, on, connected to, or coupled to the other element, layer, region, or component such that one or more intervening elements, layers, regions, or components may be present therebetween. For example, if (e.g., when) a layer, region, or component is referred to as being “electrically connected” or “electrically coupled” to another layer, region, or component, it may be directly electrically connected or coupled to the other layer, region, and/or component or one or more intervening layers, regions, or components may be present therebetween. However, “directly on/directly connected/directly coupled” refers to one component directly on or connecting or coupling another component without an intermediate component. In one or more embodiments, other expressions describing relationships between components such as “between,” “immediately between” or “adjacent to” and “directly adjacent to” may be construed similarly. In addition, it will also be understood that if (e.g., when) an element or layer is referred to as being “between” two elements or layers, it may be the only element or layer between the two elements or layers, or one or more intervening elements or layers may also be present.

For the purposes of the present disclosure, expressions such as “at least one of,” “one of,” and “selected from among,” if (e.g., when) preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, XZ, YZ, and ZZ, or any variation thereof. Similarly, the expression such as “at least one of A and/or B” may include A, B, or A and B. As used herein, the term “and/or” includes any and all combinations of one or more of the associated listed items. For example, the expression such as “A and/or B” may include A, B, or A and B. Further, the use of “may” when describing embodiments of the present disclosure refers to “one or more embodiments of the present disclosure”.

It will be understood that, although the terms “first,” “second,” “third,” and/or the like, may be used herein to describe one or more suitable elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section described herein could be termed a second element, component, region, layer, or section, without departing from the spirit and scope of the present disclosure.

In the example embodiments, the x-axis, the y-axis, and/or the z-axis are not limited to three axes of a cubic coordinate system, and may be interpreted in a broader sense. For example, the x-axis, the y-axis, and the z-axis may be normal (e.g., perpendicular) to one another, or may represent different directions that are not normal (e.g., perpendicular) to one another. The same applies for first, second, and/or third directions.

The terminology used herein is for the purpose of describing particular embodiments only and is not intended to be limiting of the present disclosure. As used herein, the singular forms “a” and “an” and “the” are intended to include the plural forms as well, unless the context clearly indicates otherwise. It will be further understood that the terms “comprise(s),” “comprising,” “have (has),” “having,” “include(s),” and “including,” if (e.g., when) used in the disclosure, specify the presence of the stated features, integers, numbers, steps, operations, elements, and/or components, but do not preclude the presence or addition of one or more other features, integers, numbers, steps, operations, elements, components, and/or groups thereof. Additionally, the terms “comprise(s)/comprising,” “include(s)/including,” “have/has/having”, or other similar terms include or support the terms “consisting of” and “consisting essentially of,” indicating the presence of stated features, integers, numbers, steps, operations, elements, and/or components, without or essentially without the presence of other features, integers, numbers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and refers to within an acceptable range of deviation for the particular value as determined by one of ordinary skill in the art, considering the measurement in question and the error associated with measurement of the particular quantity (i.e., the limitations of the measurement system). For example, “about” may refer to within one or more standard deviations, or within +30%, 20%, 10%, or 5% of the stated value.

If (e.g., when) one or more embodiments may be implemented differently, a specific process order may be performed differently from the described order. For example, two consecutively described processes may be performed substantially at the same time or performed in an order opposite to the described order.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this disclosure such that amending to expressly recite any such subranges would comply with the requirements of 35 U.S.C. § 112(a) and 35 U.S.C. § 132(a).

The light emitting elements, the display devices/apparatuses, the electronic or electric devices/apparatuses, the manufacturing apparatuses thereof, and/or any other relevant devices or components according to one or more embodiments of the present disclosure described herein may be implemented utilizing any suitable hardware, firmware (e.g., an application-specific integrated circuit), software, or a (e.g., any suitable) combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate.

Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, and/or the like. Also, a person of skill in the art should recognize that the functionality of various computing devices may be combined or integrated into a single computing device, or the functionality of a particular computing device may be distributed across one or more other computing devices without departing from the spirit and scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning for example consistent with their meaning in the context of the relevant art and/or the present specification, and should not be interpreted in an idealized or overly formal sense, unless expressly so defined herein.

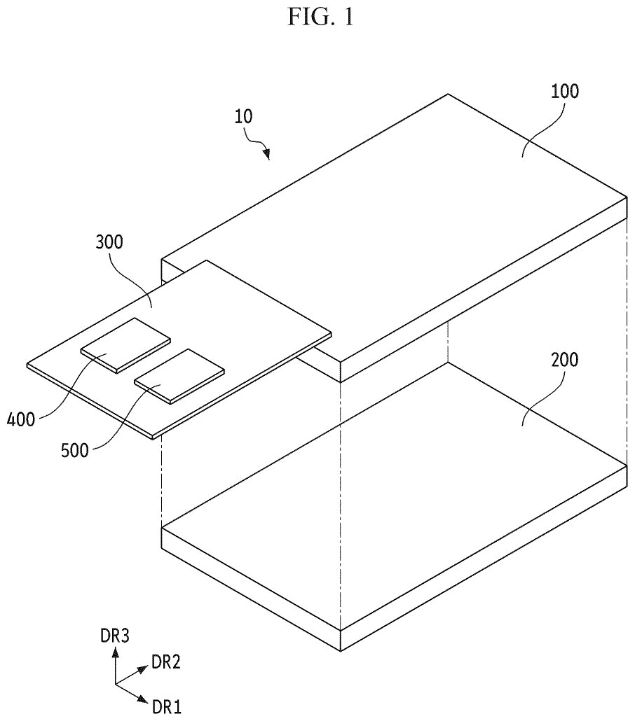

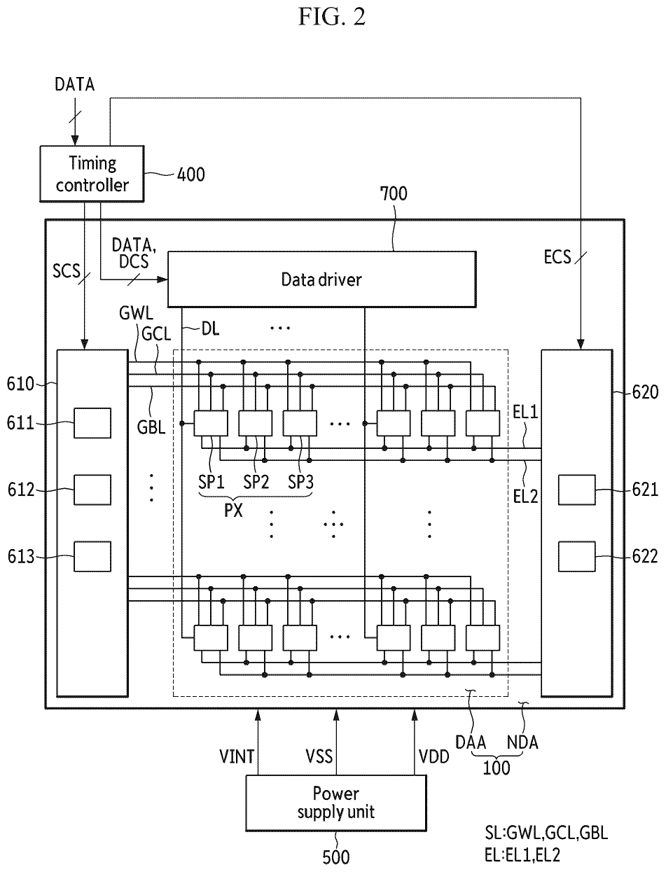

FIG. 1 is an exploded perspective view illustrating a display device according to one or more embodiments of the present disclosure. FIG. 2 is a block diagram illustrating a display device according to one or more embodiments of the present disclosure.

Referring to FIG. 1 and FIG. 2, a display device 10 according to one or more embodiments may be a device that displays a moving image or a still image. The display device 10 according to one or more embodiments may be applied to portable electronic devices such as a mobile phone, a smart phone, a tablet personal computer, a mobile communication terminal, an electronic notebook, an e-book, a portable multimedia player (PMP), a navigation system, an ultra mobile PC (UMPC), and/or the like. For example, in one or more embodiments, the display device 10 according to one or more embodiments may be applied as a display on a television, a laptop, a monitor, a billboard, or an Internet of Things (IOT). In one or more embodiments, the display device 10 may be applied to a smart watch, a watch phone, or a head-mounted display (HMD) for implementing virtual reality and/or augmented reality.

The display device 10 according to one or more embodiments includes a display panel 100, a heat dissipation layer 200, a circuit board 300, a timing control circuit 400, and a power supply circuit 500.

In one or more embodiments, the display panel 100 may be in a planar shape, such as a rectangle. For example, the display panel 100 may have a rectangle-like planar shape with short sides in a first direction DR1 and long sides in a second direction DR2 that intersects the first direction DR1. The corners of the display panel 100 where the short side in the first direction DR1 and the long side in the second direction DR2 meet may be rounded to have a set or predetermined curvature or may be formed at right angles. The planar shape of the display panel 100 is not limited to a rectangle, but may be formed similarly to other polygons, circles, or ovals. A planar shape of the display device 10 may follow the planar shape of the display panel 100, but embodiments of the present disclosure are not limited thereto.

The display panel 100 may include a plurality of pixels PX, a plurality of scan lines SL, a plurality of light emitting control lines EL, and a plurality of data lines DL, a scan driving portion 610, a light emitting driving portion 620, and a data driving portion 700 (also referred to as Data driver). The display panel 100 may be divided into a display area DAA that displays an image and a non-display area NDA that does not display an image, as shown in FIG. 2.

A plurality of pixels PX may be arranged in the display area DAA. The plurality of pixels PX may be arranged in a matrix form in the first direction DR1 and the second direction DR2. The plurality of scan lines SL and the plurality of light emitting control lines EL may extend in the first direction DR1 and be arranged in the second direction DR2. The plurality of data lines DL may extend in the second direction DR2 and be arranged in the first direction DR1.

The plurality of scan lines SL includes a plurality of write scan lines GWL, a plurality of control scan lines GCL, and a plurality of bias scan lines GBL. The plurality of light emitting control lines EL includes a plurality of first light emitting control lines EL1 and a plurality of second light emitting control lines EL2.

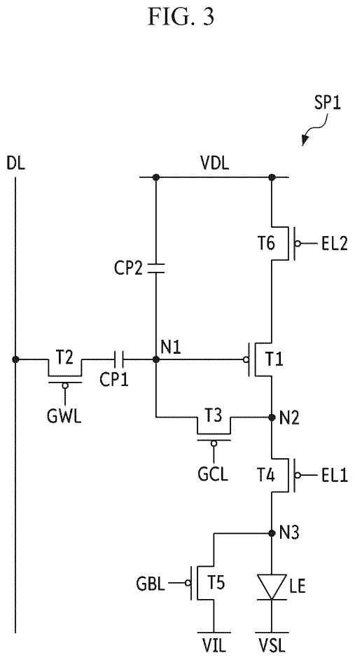

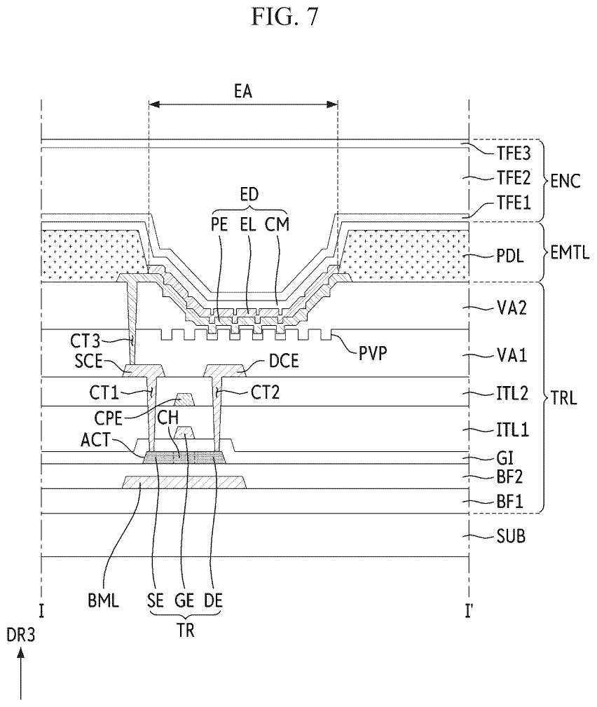

The plurality of pixels PX includes a plurality of sub-pixels SP1, SP2, and SP3. For example, each pixel PX may include a set of sub-pixels SP1, SP2, and SP3. Each subpixel selected from among the plurality of sub-pixels SP1, SP2, and SP3 may include a plurality of pixel transistors as shown in FIG. 3, and the plurality of pixel transistors may be formed by a semiconductor process and may be arranged on a semiconductor substrate (SSUB in FIG. 7). For example, in one or more embodiments, the plurality of pixel transistors of the data driving portion 700 may be formed by a complementary metal oxide semiconductor (CMOS), but embodiments of the present disclosure are not limited thereto.

Each of the plurality of sub-pixels SP1, SP2, and SP3 may be connected to one write scan line GWL, one control scan line GCL, one bias scan line GBL, one first light emitting control line EL1, one second light emitting control line EL2, and one data line DL. Each of the plurality of sub-pixels SP1, SP2, and SP3 may be supplied with a data voltage of the data line DL according to a write scan signal of the write scan line GWL and may be to emit light from a light emitting element according to the data voltage.

The scan driving portion 610, the light emitting driving portion 620, and the data driving portion 700 may be arranged in the non-display area NDA.

The scan driving portion 610 includes a plurality of scan transistors, and the light emitting driving portion 620 includes a plurality of light emitting transistors. The plurality of scan transistors and the plurality of light emitting transistors may be formed by a semiconductor process and may be formed on a semiconductor substrate (SSUB in FIG. 7). For example, in one or more embodiments, the plurality of scan transistors and the plurality of light emitting transistors may be formed of CMOS, but embodiments of the present disclosure are not limited thereto.

The scan driving portion 610 may include a write scan signal output portion 611, a control scan signal output portion 612, and a bias scan signal output portion 613. Each of the write scan signal output portion 611, the control scan signal output portion 612, and the bias scan signal output portion 613 may receive a scan timing control signal SCS from the timing control circuit 400 (also referred to as Timing controller). The write scan signal output portion 611 may generate write scan signals according to the scan timing control signal SCS of the timing control circuit 400 and sequentially output the same to the write scan lines GWL. The control scan signal output portion 612 may generate control scan signals according to the scan timing control signal SCS and sequentially output the same to the control scan lines GCL. The bias scan signal output portion 613 may generate bias scan signals according to the scan timing control signal SCS and sequentially output them to bias scan lines GBL.

The light emitting driving portion 620 may include a first light emitting control driving portion 621 and a second light emitting control driving portion 622. Each of the first light emitting control driving portion 621 and the second light emitting control driving portion 622 may receive a light emitting timing control signal ECS from the timing control circuit 400. The first light emitting control driving portion 621 may generate first light emitting control signals according to the light emitting timing control signal ECS and sequentially output them to the first light emitting control lines EL1. The second light emitting control driving portion 622 may generate second light emitting control signals according to the light emitting timing control signal ECS and sequentially output them to the second light emitting control lines EL2.

The data driving portion 700 may include a plurality of data transistors, and the plurality of data transistors may be formed by a semiconductor process and may be formed on a semiconductor substrate (SSUB in FIG. 7). For example, in one or more embodiments, the plurality of data transistors may be formed by CMOS, but embodiments of the present disclosure are not limited thereto.

The data driving portion 700 may receive digital video data DATA and a data timing control signal DCS from the timing control circuit 400. The data driving portion 700 converts the digital video data DATA into analog data voltages according to the data timing control signal DCS and outputs them to the data lines DL. In this regard, the sub-pixels SP1, SP2, and/or SP3 are selected by the write scan signal of the scan driving portion 610, and the data voltages may be supplied to the selected sub-pixels SP1, SP2, and/or SP3.

The heat dissipation layer 200 may overlap the display panel 100 in a third direction DR3, which is the thickness direction of the display panel 100. The heat dissipation layer 200 may be arranged on a (e.g., one) side of the display panel 100, for example, a back surface of the display panel 100. The heat dissipation layer 200 serves to dissipate heat generated in the display panel 100. The heat dissipation layer 200 may include a metal layer formed of, such as, graphite, silver (Ag), copper (Cu), and/or aluminum (AI), which has high thermal conductivity.

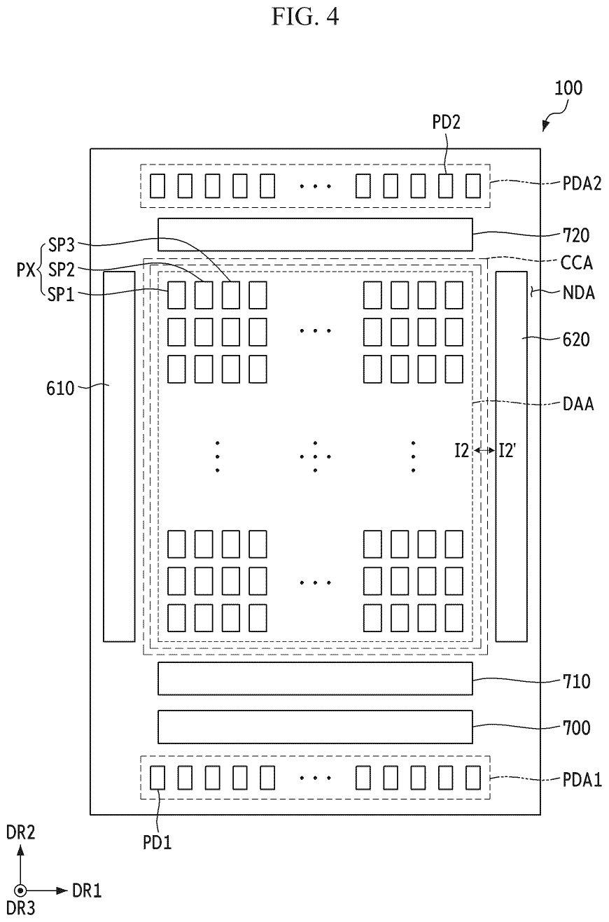

The circuit board 300 may be electrically connected to a plurality of first pads (PD1 in FIG. 4) of a first pad portion (PDA1 in FIG. 4) of the display panel 100 using a conductive adhesive material such as an anisotropic conductive film. In one or more embodiments, the circuit board 300 may be a flexible printed circuit board having a flexible material, or a flexible film. In FIG. 1, the circuit board 300 is illustrated as being unfolded, but, in one or more embodiments, the circuit board 300 may be bent. In these embodiments, one end of the circuit board 300 may be arranged on the back surface of the display panel 100 and/or a back surface of the heat dissipation layer 200. The other end of the circuit board 300 may be connected to the plurality of first pads (PD1 in FIG. 4) of the first pad portion (PDA1 in FIG. 4) of the display panel 100 using a conductive adhesive material. One end of the circuit board 300 may be opposite to the other end of the circuit board 300.

The timing control circuit 400 may receive digital video data and timing signals from the outside. The timing control circuit 400 may generate the scan timing control signal SCS, the light emitting timing control signal ECS, and the data timing control signal DCS for controlling the display panel 100 according to the timing signals. The timing control circuit 400 may output the scan timing control signal SCS to the scan driving portion 610 and output the light emitting timing control signal ECS to the light emitting driving portion 620. The timing control circuit 400 may output digital video data DATA and the data timing control signal DCS to the data driving portion 700.

The power supply circuit 500 (also referred to as Power supply unit) may generate a plurality of panel driving voltages according to a power supply voltage from the outside. For example, in one or more embodiments, the power supply circuit 500 may generate a first driving voltage VSS, a second driving voltage VDD, and a third driving voltage VINT and supply them to the display panel 100. The descriptions of the first driving voltage VSS, the second driving voltage VDD, and the third driving voltage VINT will be described in more detail later with reference to FIG. 3.

The timing control circuit 400 and the power supply circuit 500 may each be formed as an integrated circuit (IC) and attached to one side of the circuit board 300. In this regard, the scan timing control signal SCS, the light emitting timing control signal ECS, the digital video data DATA, and the data timing control signal DCS of the timing control circuit 400 may be supplied to the display panel 100 through the circuit board 300. Additionally, the first driving voltage VSS, the second driving voltage VDD, and the third driving voltage VINT of the power supply circuit 500 may be supplied to the display panel 100 through the circuit board 300.

In one or more embodiments, each of the timing control circuit 400 and the power supply circuit 500 may be arranged in the non-display area NDA of the display panel 100 similarly to the scan driving portion 610, the light emitting driving portion 620, and the data driving portion 700. In these embodiments, the timing control circuit 400 may include a plurality of timing transistors, and the power supply circuit 500 may include a plurality of power transistors. The plurality of timing transistors and the plurality of power transistors may be formed by a semiconductor process and may be formed on a semiconductor substrate (SSUB in FIG. 7). For example, in one or more embodiments, the plurality of timing transistors and the plurality of power transistors may each be formed by CMOS, but embodiments of the present disclosure are not limited thereto. In one or more embodiments, each of the timing control circuit 400 and the power supply circuit 500 may be arranged between the data driving portion 700 and the first pad portion (PDA1 in FIG. 4).

FIG. 3 is an equivalent circuit diagram of a first sub-pixel according to one or more embodiments of the present disclosure.

Referring to FIG. 3, a first sub-pixel SP1 may be connected to a write scan line GWL, a control scan line GCL, a bias scan line GBL, a first light emitting control line EL1, a second light emitting control line EL2, and a data line DL. Further, the first sub-pixel SP1 may be connected to a first driving voltage line VSL to which a first driving voltage VSS corresponding to a low potential voltage is applied, a second driving voltage line VDL to which a second driving voltage VDD corresponding to a high potential voltage is applied, and a third driving voltage line VIL to which a third driving voltage VINT corresponding to an initialization voltage is applied.

In one or more embodiments, the first sub-pixel SP1 includes a plurality of transistors T1 to T6, a light emitting element LE, a first capacitor CP1, and a second capacitor CP2.

The light emitting element LE emits light according to a driving current flowing in a channel of a first transistor T1. The amount (e.g., emission intensity) of light emitted by the light emitting element LE may be proportional to the driving current. A first electrode of the light emitting element LE may be an anode electrode, and a second electrode of the light emitting element LE may be a cathode electrode. The light emitting element LE may be an organic light emitting diode including the first electrode, the second electrode, and an organic light emitting layer arranged between the first electrode and the second electrode, but embodiments of the present disclosure are not limited thereto. For example, in one or more embodiments, the light emitting element LE may be an inorganic light emitting element including a first electrode, a second electrode, and an inorganic semiconductor arranged between the first electrode and the second electrode, in these embodiments, the light emitting element LE may be a micro light emitting diode.

The first transistor T1 may be a driving transistor that controls a source-drain current (Ids, hereinafter referred to as “driving current”) flowing between a source electrode and a drain electrode according to a voltage applied to a gate electrode thereof.

A second transistor T2 may be arranged between one electrode of the first capacitor CP1 and the data line DL. The second transistor T2 is turned on by the write scan signal of the write scan line GWL to connect the one electrode of the first capacitor CP1 to the data line DL. As a result, the data voltage of the data line DL may be applied to the one electrode of the first capacitor CP1.

A third transistor T3 may be arranged between a first node N1 and a second node N2. The third transistor T3 is turned on by the write control signal of the write control line GCL to connect the first node N1 to the second node N2. Accordingly, if (e.g., when) the gate electrode and the drain electrode of the first transistor T1 are connected, the first transistor T1 may operate like a diode.

A fourth transistor T4 may be connected between the second node N2 and a third node N3. The fourth transistor T4 is turned on by the first light emitting control signal of the first light emitting control line EL1 to connect the second node N2 to the third node N3. Accordingly, the driving current of the first transistor T1 may be supplied to the light emitting element LE. A fifth transistor T5 may be arranged between the third node N3 and the third driving voltage line VIL. The fifth transistor T5 is turned on by the bias scan signal of the bias scan line GBL to connect the third node N3 to the third driving voltage line VIL. As a result, the third driving voltage VINT of the third driving voltage line VIL may be applied to the first electrode of the light emitting element LE.

A sixth transistor T6 may be arranged between the source electrode of the first transistor T1 and the second driving voltage line VDL. The sixth transistor T6 is turned on by the second light emitting control signal of the second light emitting control line EL2 to connect the source electrode of the first transistor T1 to the second driving voltage line VDL. As a result, the second driving voltage VDD of the second driving voltage line VDL may be applied to the source electrode of the first transistor T1.

The first capacitor CP1 is formed between the first node N1 and a drain electrode of the second transistor T2. The second capacitor CP2 is formed between a gate electrode of the first transistor T1 and the second driving voltage line VDL. Each of the first to sixth transistors T1 to T6 may be a metal-oxide-semiconductor field effect transistor (MOSFET). For example, in one or more embodiments, each of the first to sixth transistors T1 to T6 may be a P-type (kind) MOSFET, but embodiments of the present disclosure are not limited thereto. In one or more embodiments, each of the first to sixth transistors T1 to T6 may be an N-type (kind) MOSFET. In one or more embodiments, some of the transistors selected from among the first to sixth transistors T1 to T6 may be a P-type (kind) MOSFET, and the remaining transistors may be an N-type (kind) MOSFET.

Although FIG. 3 illustrates that the first sub-pixel SP1 includes six transistors T1 to T6 and two capacitors C1 and C2, the equivalent circuit diagram of the first sub-pixel SP1 is not limited to that shown in FIG. 3. For example, the number of transistors and the number of capacitors of the first sub-pixel SP1 are not limited to those shown in FIG. 3.

In addition, an equivalent circuit diagram of the second sub-pixel SP2 and an equivalent circuit diagram of the third sub-pixel SP3 may each be substantially the same as the equivalent circuit diagram of the first sub-pixel SP1 described in conjunction with FIG. 3. Therefore, the descriptions of the equivalent circuit diagram of the second sub-pixel SP2 and the equivalent circuit diagram of the third sub-pixel SP3 are not provided in this disclosure.

FIG. 4 is a layout diagram illustrating an example of a display panel according to one or more embodiments of the present disclosure.

Referring to FIG. 4, a display area DAA of a display panel 100 according to one or more embodiments includes a plurality of pixels PX arranged in a matrix form. A non-display area NDA of the display panel 100 according to one or more embodiments includes a scan driving portion 610, a light emitting driving portion 620, a data driving portion 700, a first distribution circuit 710, a second distribution circuit 720, a first pad portion PDA1, and a second pad portion PDA2.

The scan driving portion 610 may be arranged on a first side of the display area DAA, and the light emitting driving portion 620 may be arranged on a second side of the display area DAA. For example, in one or more embodiments, the scan driving portion 610 may be arranged on one side of the display area DAA in the first direction DR1, and the light emitting driving portion 620 may be arranged on the other side of the display area DAA in the first direction DR1. However, embodiments of the present disclosure are not limited thereto, for example, the scan driving portion 610 and the light emitting driving portion 620 may be arranged on both (e.g., simultaneously) the first side and the second side of the display area DAA.

The first pad portion PDA1 may include a plurality of first pads PD1 connected to pads or bumps of the circuit board 300 through a conductive adhesive material. The first pad portion PDA1 may be arranged on a third side of the display area DAA. For example, in one or more embodiments, the first pad portion PDA1 may be arranged on one side of the display area DAA in the second direction DR2. The first pad portion PDA1 may be arranged on the outside of the data driving portion 700 in the second direction DR2.

The second pad portion PDA2 may include a plurality of second pads PD2 corresponding to test pads for testing whether the display panel 100 operates normally. The plurality of second pads PD2 may be connected to a jig or probe pin in an inspection process or may be connected to a circuit board for inspection. The circuit board for inspection may be a printed circuit board made of a rigid material or a flexible printed circuit board made of a flexible material.

The second pad portion PDA2 may be arranged on a fourth side of the display area DAA. For example, in one or more embodiments, the second pad portion PDA2 may be arranged on the other side of the display area DAA in the second direction DR2. The second pad portion PDA2 may be arranged on the outside of the second distribution circuit 720 in the second direction DR2.

The first distribution circuit 710 distributes data voltages applied through the first pad portion PDA1 to a plurality of data lines DL. For example, in one or more embodiments, the first distribution circuit 710 may distribute data voltages applied through one first pad PD1 of the first pad portion PDA1 to P (P is a positive integer greater than or equal to 2) data lines DL, thereby reducing the number of first pads PD1. The first distribution circuit 710 may be arranged on the third side of the display area DAA of the display panel 100. For example, the first distribution circuit 710 may be arranged on one side of the display area DAA in the second direction DR2.

The second distribution circuit 720 distributes signals applied through the second pad portion PDA2 to the scan driving portion 610, the light emitting driving portion 620, and the data lines DL. The second pad portion PDA2 and the second distribution circuit 720 may be configured to inspect an operation of each of the pixels PX of the display area DAA. The second distribution circuit 720 may be arranged on the fourth side of the display area DAA of the display panel 100. For example, the second distribution circuit 720 may be arranged on the other side of the display area DAA in the second direction DR2, with respect to the first distribution circuit 710.

In the context of the present disclosure and unless defined otherwise, “one side of the display area DAA in the second direction DR2” refers to a specific side of the display area along the direction labeled as DR2. For instance, if DR2 represents a vertical direction, this may indicate the bottom side of the display area. Conversely, “the other side of the display area DAA in the second direction DR2” refers to the opposite side of the display area along the same direction DR2, which, continuing the previous example, may indicate the top side of the display area. These phrases are used to describe the positioning of components, such as distribution circuits, on opposite sides of the display area along the specified direction DR2.

A cathode connection portion CCA may be an area where a second electrode (CM in FIG. 7) of a light emitting element layer (EMTL in FIG. 7) is connected to the first driving voltage line VSL of the non-display area NDA. The cathode connection portion CCA may be arranged on at least one outer side of the display area DA. For example, in one or more embodiments, the cathode connection portion CCA may be arranged on at least one outer side among the left, right, top, and bottom sides of the display area DA. In one or more embodiments, the cathode connection portion CCA may be arranged to be around (e.g., surround) the display area DA as shown in FIG. 4 to minimize or reduce the deviation of the first driving voltage VSS due to IR dropping or IR rising of the second electrode in the display area DA.

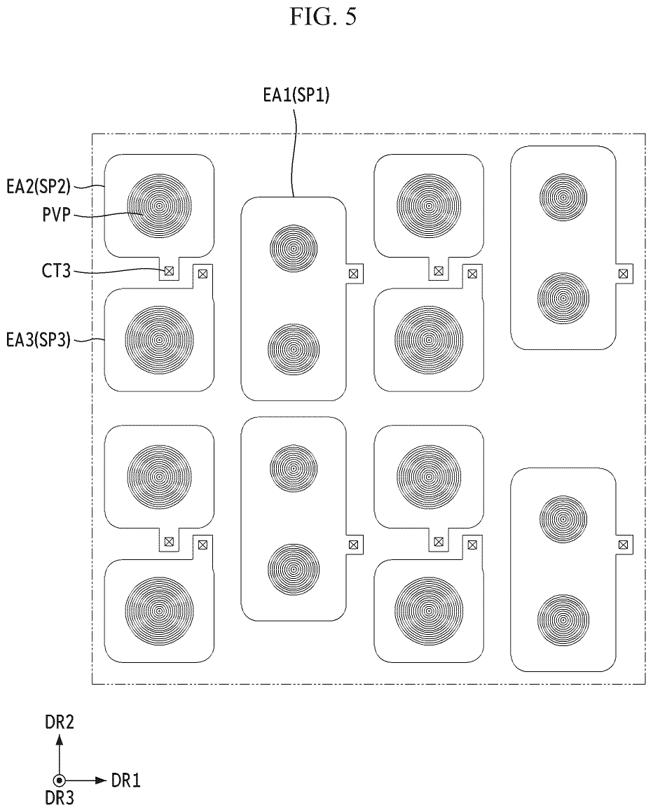

FIG. 5 is a layout diagram illustrating an example of a display area of FIG. 4 according to one or more embodiments of the present disclosure.

As shown in FIG. 5, each of the plurality of pixels PX includes a first light emitting area EA1, which is a light emitting area of the first sub-pixel SP1, a second light emitting area EA2, which is a light emitting area of the second sub-pixel SP2, and a third light emitting area EA3, which is a light emitting area of the third sub-pixel SP3. In addition, each of the light emitting areas may include a contact hole CT3 which will be discussed later.

In one or more embodiments, the first light emitting area EA1, the second light emitting area EA2, and the third light emitting area EA3 may each have a square planar shape as shown in FIG. 5, but embodiments of the present disclosure are not limited thereto. The first light emitting area EA1, the second light emitting area EA2, and the third light emitting area EA3 may have other polygonal, circular, elliptical, or non-rectangular planar shapes other than rectangular shapes.

As shown in FIG. 5, in one or more embodiments, the first light emitting area EA1 and the second light emitting area EA2 in each of the plurality of pixels PX may be neighboring in the first direction DR1. Further, the first light emitting area EA1 and the third light emitting area EA3 may be neighboring in the first direction DR1. Furthermore, the second light emitting area EA2 and the third light emitting area EA3 may be neighbors in the second direction DR2. The area of the first light emitting area EA1, the area of the second light emitting area EA2, and the area of the third light emitting area EA3 may be different.

The first sub-pixel SP1 may be to emit first light, the second sub-pixel SP2 may be to emit second light, and the third sub-pixel SP3 may be to emit third light. Here, the first light may be light in a blue wavelength band, the second light may be light in a green wavelength band, and the third light may be light in a red wavelength band. For example, the blue wavelength band may refer to a wavelength band in which the main peak wavelength of light is in a wavelength band of approximately 370 nanometers (nm) to 460 nm, the green wavelength band may refer to a wavelength band in which the main peak wavelength of light is in a wavelength band of approximately 480 nm to 560 nm, and the red wavelength band may refer to a wavelength band in which the main peak wavelength of light is in a wavelength band of approximately 600 nm to 750 nm.

As shown in FIG. 5, each of the plurality of pixels PX may include three light emitting areas EA1, EA2, and EA3, but embodiments of the present disclosure are not limited thereto. For example, in one or more embodiments, each of the plurality of pixels PX may include four light emitting areas.

In one or more embodiments, the light emitting areas of the plurality of pixels PX may be arranged in a stripe structure in which the light emitting areas are arranged in a first direction DR1, a PenTile® structure in which light emitting areas EA1, EA2, EA3, and a fourth light emitting area are arranged in a rhombus shape, or a hexagonal structure in which the light emitting areas are arranged in a hexagonal shape. PenTile® is a duly registered trademark of Samsung Display Co., Ltd.

According to one or more embodiments, the first sub-pixel SP1 may have a larger area than the other sub-pixels. For example, a pixel electrode PE of the first sub-pixel SP1 may have a larger area than a pixel electrode PE of the second sub-pixel SP2 or a pixel electrode PE of the third sub-pixel SP3. The pixel electrode PE will be described in more detail later.

According to one or more embodiments, the first sub-pixel SP1 may have a larger light emitting area EA than the other pixels. For example, the light emitting area EA of the first sub-pixel SP1 may have a larger area than the light emitting area EA of the second sub-pixel SP2 or the light emitting area EA of the third sub-pixel SP3. In this regard, the first sub-pixel SP1 may have a larger number of light emitting areas EA than the other sub-pixels. For example, in one or more embodiments, the first sub-pixel SP1 may include two light emitting areas EA, and the second sub-pixel SP2 and the third sub-pixel SP3 may each include one light emitting area EA.

According to one or more embodiments, in a plan view, the pixel electrode PE and the light emitting area EA of each sub-pixel SP may each have a circular shape. However, the shape of the pixel electrode PE and the light emitting area EA is not limited thereto and may have one or more suitable shapes.

According to one or more embodiments, the light emitting area EA of each sub-pixel SP1, SP2, and SP3 may include a rough pattern, for example, an uneven pattern. The uneven pattern is formed in a concentric shape in the light emitting area EA, thereby minimizing or reducing the color difference (or color deviation) of the display device according to the viewing angle of the display device 10, which improves the image quality of the display device. Hereinafter, the uneven pattern will be specifically described in conjunction with the drawings and the more detailed descriptions will be provided later.

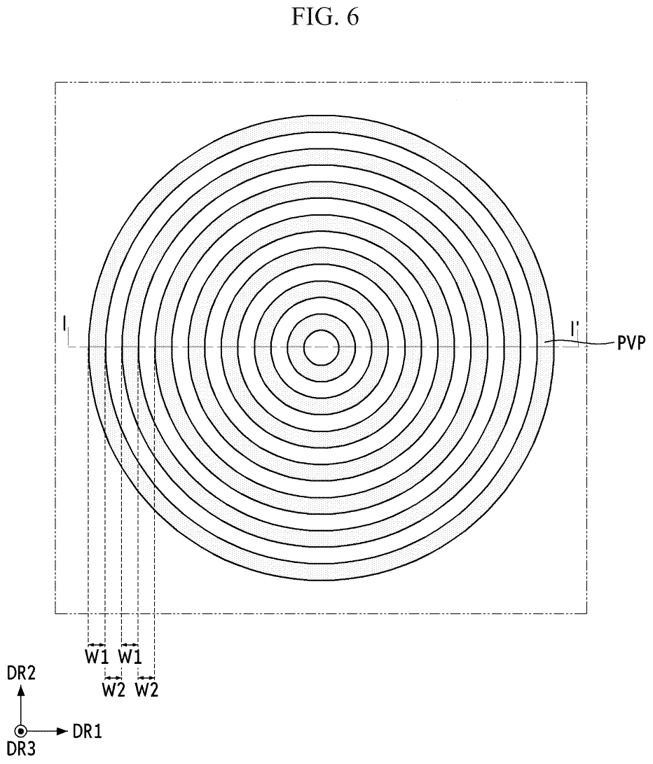

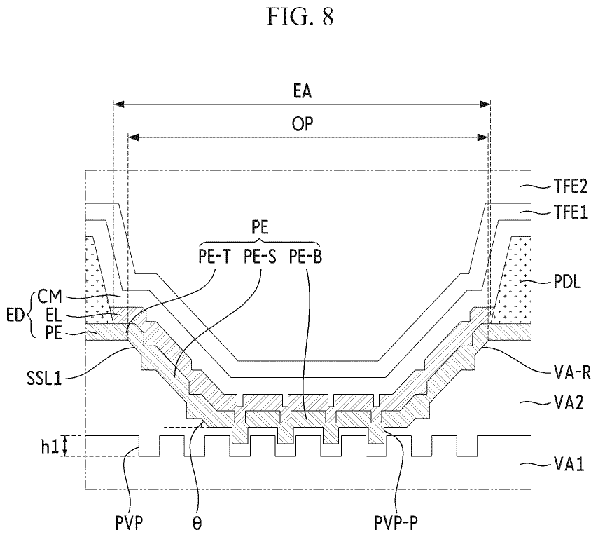

FIG. 6 is an enlarged view of a pixel according to one or more embodiments of the present disclosure. FIG. 7 is a cross-sectional view illustrating an example of a display panel cut along the line I-l′ of FIG. 6 according to one or more embodiments of the present disclosure. For example, the pixel in FIG. 6 may be an enlarged view of a portion of the sub-pixel indicated by reference number EA3 (SP3) in FIG. 5. FIG. 8 may be an enlarged view of a via layer and a light emitting element in the light emitting area of FIG. 7 according to one or more embodiments of the present disclosure.

The display device 10 of one or more embodiments may include a substrate SUB, a transistor layer TRL, a light emitting element layer EMTL, and an encapsulation layer ENC, as shown in FIG. 7. A light blocking layer BML, buffer layers BF1 and BF2, the transistor layer TRL, the light emitting element layer EMTL, and the encapsulation layer ENC may be arranged on the substrate SUB.

The substrate SUB may be a rigid substrate SUB or a flexible substrate SUB that may be bent, folded, rolled, and/or the like. The substrate SUB may be made of an insulating material such as glass, quartz, or a polymer material (e.g., a polymeric resin). Non-limiting examples of the polymer material include polyethersulphone (PES), polyacrylate (PA), polyarylate (PAR), polyetherimide (PEI), polyethylene naphthalate (PEN), polyethylene terephthalate (PET), polyphenylene sulfonate, polypropylene sulfonate, polypropylene terephthalate, polyphenylene sulfide, polyallylate, polyimide (PI), polycarbonate (PC), cellulose triacetate (CAT), cellulose acetate propionate (CAP), and/or one or more (e.g., any suitable) combinations thereof. In one or more embodiments, the substrate SUB may include a metal material.

A first buffer layer BF1 may be arranged on the substrate SUB. The first buffer layer BF1 may be a film for protecting transistors of the transistor layer TRL and a light emitting layer EL of the light emitting element layer EMTL from moisture penetrating through the substrate SUB which is vulnerable to moisture permeation. The first buffer layer BF1 may be formed of a plurality of inorganic films alternately laminated. For example, in one or more embodiments, the first buffer layer BF1 may be formed as a multi-layer of alternately stacked inorganic films of one or more selected from among a silicon nitride layer, a silicon oxynitride layer, a silicon oxide layer, a titanium oxide layer, and an aluminum oxide layer.

The light blocking layer BML may be arranged on the first buffer layer BF1. The light blocking layer BML may be arranged on the substrate SUB to overlap with an active layer ACT to be described in more detail later. The light blocking layer BML may be formed of, for example, a metal material such as chromium (Cr) and/or molybdenum (Mo), or a black ink or a black dye. In one or more embodiments, if (e.g., when) the light blocking layer BML is made of a metal material, the light blocking layer BML may be supplied with static electricity (e.g., a constant voltage). In this way, the light blocking layer BML does not electrically float, and a transistor TR on the light blocking layer BML may have its electrical characteristics stabilized. For example, the performance degradation of oxide-based transistors may be minimized or reduced. For example, oxide semiconductors are sensitive to light, and current magnitude, and/or the like may fluctuate due to light from the outside. In contrast, the light blocking layer BML may function as an opposite gate electrode of the transistor TR. The light blocking layer BML may be connected to a gate electrode GE of the transistor TR to be described in more detail below. Accordingly, the opposite gate electrode of the transistor TR and the gate electrode GE may be connected to each other.

A second buffer layer BF2 may be arranged on the light blocking layer BML. The second buffer layer BF2 may include a same material as the first buffer layer BF1 described above.

The active layer ACT may be arranged on the second buffer layer BF2. For example, the active layer ACT may be arranged on the second buffer layer BF2 to overlap the light blocking layer BML. The active layer ACT may be, for example, an oxide semiconductor. For example, in one or more embodiments, the active layer ACT may be a semiconductor including Indium-Gallium-Zinc-Oxide (IGZO) or Indium-Gallium-Zinc-Tin Oxide (IGZTO). In one or more embodiments, the active layer ACT may be, for example, crystalline silicon, polycrystalline silicon, or amorphous silicon.

A gate insulating layer GI may be arranged on the active layer ACT. For example, the gate insulating layer GI may be arranged to overlap with a channel region (CH) of the active layer ACT. The gate insulating layer GI may include at least one of tetraethoxysilane (TetraEthylOrthoSilicate, TEOS), silicon nitride (SiNₓ), or silicon oxide (SiO₂). For example, in one or more embodiments, the gate insulating layer GI may have a double-layer structure in which a silicon nitride film having a thickness of 40 nanometers (nm) and a tetraethoxysilane film having a thickness of 80 nm are sequentially laminated.

The gate electrode GE may be arranged on the gate insulating layer GI. The gate electrode GE may be arranged on the gate insulating layer GI to overlap with the channel region CH of the active layer ACT. The gate electrode GE may be made of aluminum (Al), titanium (Ti), and/or the like. In one or more embodiments, the gate electrode GE may have a double-layer or triple-layer structure in which aluminum (Al) and titanium (Ti) are laminated.

A first interlayer insulating layer ITL1 may be arranged on the gate electrode GE. The first interlayer insulating layer ITL1 may be arranged on the entire surface of the substrate SUB including the gate electrode GE. The first interlayer insulating layer ITL1 may include an inorganic film, such as a silicon nitride layer, a silicon oxynitride layer, a silicon oxide layer, a titanium oxide layer, and/or an aluminum oxide layer. In one or more embodiments, the first interlayer insulating layer ITL1 may include a plurality of inorganic films.

A capacitor electrode CPE may be arranged on the first interlayer insulating layer ITL1. For example, the capacitor electrode CPE may be arranged on the first interlayer insulating layer ITL1 to overlap the gate electrode GE. A capacitor may be formed in a region where the capacitor electrode CPE and the gate electrode GE overlap.

A second interlayer insulating layer ITL2 may be arranged on the capacitor electrode CPE. The second interlayer insulating layer ITL2 may be arranged on the entire surface of the substrate SUB including the capacitor electrode CPE. The second interlayer insulating layer ITL2 may include a same material as the first interlayer insulating layer ITL1 described above.

A source connection electrode SCE and a drain connection electrode DCE may be arranged on the second interlayer insulating layer ITL2. The source connection electrode SCE may be connected to a source electrode SE of the active layer ACT through a first contact hole CT1 penetrating the second interlayer insulating layer ITL2, the first interlayer insulating layer, and the gate insulating layer GI. The drain connection electrode DCE may be connected to a drain electrode DE of the active layer ACT through a second contact hole CT2 penetrating the second interlayer insulating layer ITL2, the first interlayer insulating layer ITL1, and the gate insulating layer Gl.

A first protective layer VA1 may be arranged on the source connection electrode SCE and the drain connection electrode DCE. For example, the first protective layer VA1 may be arranged on the entire surface of the substrate including the source connection electrode SCE and the drain connection electrode DCE. The first protective layer VA1 may be made of a same material as the first interlayer insulating layer ITL1.

The first protective layer VA1 may include an uneven pattern PVP formed in an area overlapping a light emitting area EA in a thickness direction (the third direction DR3). Referring to FIG. 6, the uneven pattern PVP may have a shape of closed curves having the same center on a plane. For example, in one or more embodiments, the uneven pattern PVP may have concentric circle shapes on a plane. In this disclosure, “on a plane” is set based on a plane parallel to a plane defined by the first direction DR1 and the second direction DR2. In this disclosure, “in cross section” is defined as a state viewed from the first direction DR1 or the second direction DR2. In the context of the present disclosure and unless otherwise defined, “on a plane” or “a plan view” may refer to an orthographic projection of a three-dimensional object from the position of a horizontal plane intersecting the object. That is, it is a top-down view, showing the layout and spatial relationships of various elements within the object or structure. “On a plane” or “a plan view” based on the third direction DR3 (e.g., a thickness direction) refers to a top-down view of the object, as if looking directly down onto the surface from above. In this context, the third direction DR3 is perpendicular or normal to a plane defined by the first direction DR1 and the second direction DR2.

The uneven pattern PVP may be an engraved pattern and may have a side surface that is vertical or inclined toward a front or back surface direction of the first protective layer VA1.

Referring to FIG. 6 and FIG. 7, in one or more embodiments, a depth h1 (see FIG. 8) of the uneven pattern PVP may be about 0.5 μm to about 1.0 μm. A width w1 of the uneven pattern may be about 1.0 μm to about 2.0 μm, and an interval w2 of the uneven pattern may be formed to be about 1.0 μm to about 2.0 μm. The width w1 of the uneven pattern PVP and the interval w2 of the uneven pattern PVP may be the same, but embodiments of the present disclosure are not limited thereto.

A second protective layer VA2 may be arranged on the first protective layer VA1 including the uneven pattern PVP. For example, the second protective layer VA2 may be arranged on a front surface of the substrate SUB. For example, the second protective layer VA2 may be arranged on a front surface of the first protective layer VA1. The second protective layer VA2 may be made of a same material as the first interlayer insulating layer ITL1. The second protective layer VA2 may define a recess VA-R (see FIG. 8). The recess VA-R may overlap with the light emitting area EA. An upper opening OP (see FIG. 8) of the recess VA-R may be smaller than the light emitting area EA defined by a pixel definition layer PDL.

A depth of the recess VA-R may be smaller than a thickness of the second protective layer VA2.

A bottom surface of the second protective layer VA2 is formed with an uneven pattern according to the uneven pattern of the first protective layer VA1. The uneven pattern of the second protective layer VA2 may have a shape (e.g., a pattern) similar to the uneven pattern of the first protective layer VA1.

On the second protective layer VA2, the light emitting element layer EMTL including a light emitting element ED and the pixel definition layer PDL may be arranged.

The light emitting element ED may include a pixel electrode PE, a light emitting layer EL, and a common electrode CM. The light emitting area EA represents an area where the pixel electrode PE, the light emitting layer EL, and the common electrode CM are sequentially laminated, and holes from the pixel electrode PE and electrons from the common electrode CM are combined with each other in the light emitting layer EL to emit light. In this case, the pixel electrode PE may be an anode electrode of the light emitting element ED, and the common electrode CM may be a cathode electrode of the light emitting element ED. In one or more embodiments, the pixel electrode PE may also be referred to as the first electrode of the light emitting element ED, and the common electrode CM may also be referred to as the second electrode of the light emitting element ED.

The pixel electrode PE may be connected to the source connection electrode SCE through a third contact hole CT3 penetrating the first protective layer VA1 and the second protective layer VA2. The pixel electrode PE may be connected to the source electrode SE of the active layer ACT through the source connection electrode SCE.

Referring to FIG. 8, the pixel electrode PE may be arranged to overlap the recess VA-R defined by the second protective layer VA2. The pixel electrode PE is arranged along a sloped surface SSL1 of the recess VA-R. Therefore, the pixel electrode PE may have an inclined structure. The pixel electrode PE may include a sloped portion PE-S arranged on the sloped surface SSL1 of the recess VA-R, a bottom portion PE-B connected to a bottom portion of the sloped portion PE-S, and a top portion PE-T connected to a top portion of the sloped portion PE-S and arranged on a top portion of the second protective layer VA2. An inclination angle of the sloped portion PE-S of the pixel electrode PE may be the same as an inclination angle θ of the sloped surface SSL1 of the recess VA-R. For example, the inclination angle θ of the recess VA-R may be 20 degrees to 70 degrees. As the inclination angle θ increases, a viewing angle may narrow, and as the inclination angle θ decreases, brightness may improve. The pixel electrode PE may have a concave shape. The sloped portion PE-S surrounds the bottom portion PE-B, and the sloped portion PE-S and the bottom portion PE-B do not overlap vertically. The bottom portion PE-B and the top portion PE-T may be considered to be substantially flat (e.g., relatively flat) but may be formed to have a curvature in the process. Even if (e.g., when) the bottom portion PE-B and the top portion PE-T have a curvature in the process, they may be formed to be relatively flat compared to the sloped portion PE-S.

The pixel electrode PE has an uneven pattern PVP-P formed in the light emitting area EA according to the uneven pattern PVP of the protective layers VA1 and VA2. For example, the uneven pattern PVP-P derived from the uneven patterns PVP of the protective layers VA1 and VA2 is formed in the sloped portion PE-S and the bottom portion PE-B of the pixel electrode PE. Accordingly, the uneven pattern PVP-P derived from the uneven patterns PVP of the protective layer VA1 and VA2 in the sloped portion PE-S and the bottom portion PE-B may have a shape substantially similar to the uneven patterns PVP or at least a portion of the uneven pattern PVP of the protective layers VA1 and VA2. In the case of the uneven pattern PVP-P of the sloped portion PE-S, although it is derived from the uneven pattern PVP of the protective layers VA1 and VA2, it may have a shape that is partially different from the uneven pattern PVP of the protective layers VA1 and VA2 due to the incline.

The light emitted from the light emitting layer EL (e.g., organic light emitting layer EL) may be effectively reflected due to the uneven pattern PVP-P of the sloped portion PE-S and the bottom portion PE-B of the pixel electrode PE. In particular, because the light emitted laterally from the organic light emitting layer EL is effectively reflected, the luminance ratio LvA per angle relative to the normal side (e.g., normal direction) may be increased, and the luminance ratio deviation per angle dLvA may be decreased.

In the top emission structure that emits light in the direction of the common electrode CM based on the organic light emitting layer EL, in one or more embodiments, the pixel electrode (PE) is formed as a monolayer of molybdenum (Mo), titanium (Ti), copper (Cu), aluminum (AI), aluminum and titanium (Ti/Al/Ti), aluminum and ITO (ITO/AI/ITO), an APC alloy, or an APC alloy and ITO (ITO/APC/ITO) to increase reflectivity. The APC alloy is an alloy of silver (Ag), palladium (Pd), and copper (Cu).

The pixel definition layer PDL serves to define the light emitting area EA of the pixel PX. To this end, the pixel definition layer PDL may be arranged on a top flat surface of the protective layer VA2 to expose a portion of the pixel electrode PE. The pixel definition layer PDL may cover at least a portion of the top portion PE-T of the pixel electrode PE. The pixel definition layer PDL does not cover the sloped portion PE-S of the pixel electrode PE. For example, the pixel definition layer PDL may not overlap the sloped portion PE-S of the pixel electrode PE. The pixel definition layer PDL may be formed of an organic film, such as an acrylic resin, an epoxy resin, a phenolic resin, a polyamide resin, a polyimide resin, and/or the like. In one or more embodiments, a spacer may be arranged on the pixel definition layer PDL. The spacer may serve to support a mask during the process of manufacturing the organic light emitting layer EL. The spacer may be formed from an organic film, such as an acrylic resin, an epoxy resin, a phenolic resin, a polyamide resin, a polyimide resin, and/or the like. In one or more embodiments, the pixel definition layer PDL may include a light absorbing material to prevent or reduce light reflection. For example, the pixel definition layer PDL may include a polyimide (PI) binder and a pigment that is a mixture of red, green, and blue colors. In one or more embodiments, the pixel definition layer PDL may include a cardo-based binder resin and a (e.g., any suitable) mixture of a lactam black pigment and a blue pigment. In one or more embodiments, the pixel definition layer PDL may include carbon black.

The organic light emitting layer EL (also referred to as light emitting layer EL) may be formed on the pixel electrode PE. The organic light emitting layer EL may include an organic material and may be to emit a set or predetermined color. For example, in one or more embodiments, the organic light emitting layer EL may include a hole transporting layer, an organic material layer, and an electron transporting layer. The organic material layer may include a host and a dopant. The organic material layer may include a material that emits a set or predetermined light and may be formed using a phosphor or fluorescent material.

For example, the organic material layer of the light emitting layer EL that emits light of a first color (e.g., blue) may be a phosphorescent material including a host material including CBP or mCP and a dopant material including (4,6-F₂ppy)₂Irpic (bis[2-(4,6-difluorophenyl)pyridinato-C²,N](picolinato)iridium(III)) or L2BD111 but embodiments of the present disclosure are not limited thereto.

The organic material layer of the light emitting layer EL that emits light of a second color (e.g., green) may include a host material including CBP or mCP and a phosphorescent material including a dopant material including Ir(ppy)₃(fac tris(2-phenylpyridine)iridium). In one or more embodiments, the organic material layer of the light emitting layer EL that emits light of the second color may include a fluorescent material including Alq₃(tris(8-hydroxyquinolinato) aluminum), but embodiments of the present disclosure are not limited thereto.

The organic material layer of the light emitting layer EL emitting light of a third color (e.g., red) includes a host material including carbazole biphenyl (CBP) or mCP (1,3-bis(carbazol-9-yl)) and a phosphorescent material including at least one selected from among PIQIr(acac)(bis(1-phenylisoquinoline) acetylacetonate iridium), PQIr(acac)(bis(1-phenylquinoline) acetylacetonate iridium), PQIr(tris(1-phenylquinoline)iridium), and PtOEP (octaethylporphyrin platinum). In one or more embodiments, the organic material layer of the light emitting layer EL emitting light of the third color may include a fluorescent material including PBD:Eu (DBM)₃ (Phen) or Perylene, but embodiments of the present disclosure are not limited thereto.

In one or more embodiments, the organic light emitting layer EL of the light emitting elements ED may be formed as a single common layer arranged entirely on different pixel electrodes PE and the pixel definition layer PDL, and the light emitting layers EL arranged on different pixel electrodes PE may be to emit light of the same color. In these embodiments, the display device 10 may further include a color adjustment layer (e.g., a color conversion layer including wavelength conversion patterns and/or a color adjustment layer including color filters CF) arranged over the light emitting elements ED.

The common electrode CM may be arranged over the organic light emitting layer EL of each of the light emitting elements ED. In one or more embodiments, the common electrode CM may be formed as a single common layer arranged over the entire surface of the display area DA, and the light emitting elements ED of the pixels may share one common electrode CM. The common electrode CM may receive a common voltage (e.g., a second pixel voltage or a cathode voltage).

The encapsulation layer ENC may be arranged on the common electrode CM and cover the light emitting element ED. In one or more embodiments, the encapsulation layer ENC may include at least one inorganic film to prevent or reduce oxygen and/or moisture from penetrating into the light emitting element layer EMTL and at least one organic film to protect the light emitting element layer EMTL from debris such as dusts.

In one or more embodiments, the encapsulation layer ENC may include a first encapsulation layer TFE1, a second encapsulation layer TFE2, and a third encapsulation layer TFE3 sequentially arranged on the light emitting element ED. The first encapsulation layer TFE1 and the third encapsulation layer TFE3 may each be an inorganic encapsulation layer, and the second encapsulation layer TFE2 arranged between them may be an organic encapsulation layer.

The first encapsulation layer TFE1 and the third encapsulation layer TFE3 may each include an inorganic insulating material. For example, each of the first encapsulation layer TFE1 and the third encapsulation layer TFE3 may include aluminum oxide, titanium oxide, tantalum oxide, hafnium oxide, zinc oxide, silicon oxide, silicon nitride, silicon oxynitride, and/or other inorganic insulating materials.

The second encapsulation layer TFE2 may include an organic insulating material. For example, the second encapsulation layer TFE2 may include an organic insulating material of the polymer family, such as an acrylic resin, an epoxy resin, a polyimide, polyethylene, and/or any other organic insulating material. The second encapsulation layer TFE2 may be formed by curing a monomer or applying a polymer.

In one or more embodiments, a touch sensor layer and/or a color filter layer may be included on the encapsulation layer ENC.

The touch sensing layer may include conductive patterns including touch electrodes. The conductive patterns may sense patterns used to detect a touch input. For example, the conductive patterns of the touch sensing layer may be utilized to detect a change in an electrical characteristic (e.g., a change in electrostatic capacity) in response to a touch input and detect the touch input.

The color filter layer may be arranged on the light emitting element layer EMTL. In one or more embodiments, the color filter layer may be arranged on the touch sensing layer and may cover the light emitting element layer EMTL, the encapsulation layer ENC, and the touch sensing layer.

The color filter layer may include a light blocking layer, color filters, and at least one overcoat layer.

The color filters may include a colorant such as a dye or a pigment that absorbs light of a wavelength band other than light of a specific wavelength band.

The overcoat layer may have light transmission properties. The overcoat layer may be arranged over the entire display area DA to flatten a step caused by the color filters and the light blocking layer and protect the display panel 100.

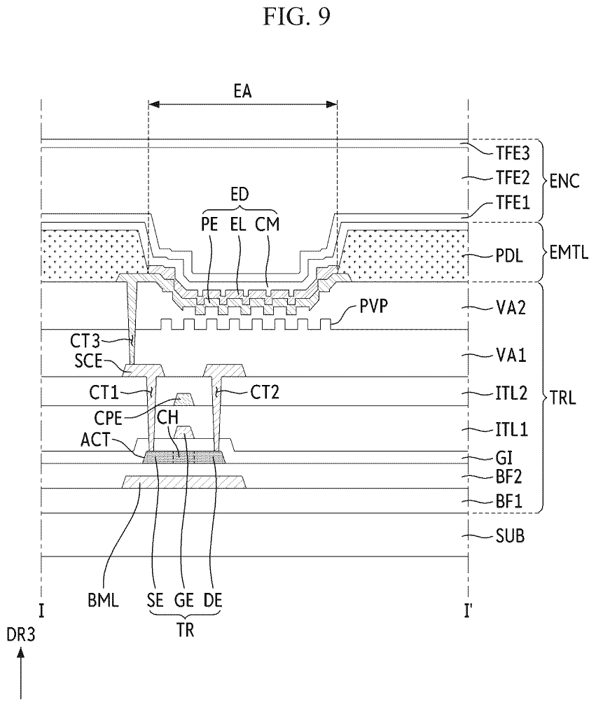

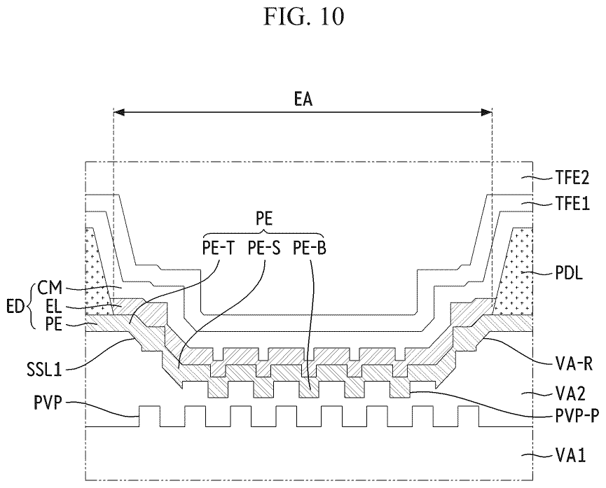

FIG. 9 is a cross-sectional view illustrating an example of a display panel cut along the I-I′ of FIG. 6 according to one or more embodiments of the present disclosure. FIG. 10 may be an enlarged view of a via layer and a light emitting element in the light emitting area of FIG. 9 according to one or more embodiments of the present disclosure.

The embodiments of FIG. 9 and FIG. 10 differ from the embodiments of FIG. 7 and FIG. 8 in that the uneven pattern PVP of the protective layers VA1 and VA2 and the uneven pattern PVP-P of the pixel electrode PVP are formed in relief. In one or more embodiments of FIG. 9 and FIG. 10, any description overlapping with the embodiments of FIG. 7 and FIG. 8 will not be provided for conciseness.

Referring to FIG. 9 and FIG. 10, the uneven pattern PVP is formed in relief in the light emitting area EA of the first protective layer VA1, and a relief uneven pattern is also formed in the second protective layer VA2 arranged on the first protective layer VA1 along the uneven pattern PVP of the first protective layer VA1.

An uneven pattern PVP-P derived from the uneven pattern of the second protective layer VA2 may also be formed in the pixel electrode PE arranged on the second protective layer VA2.

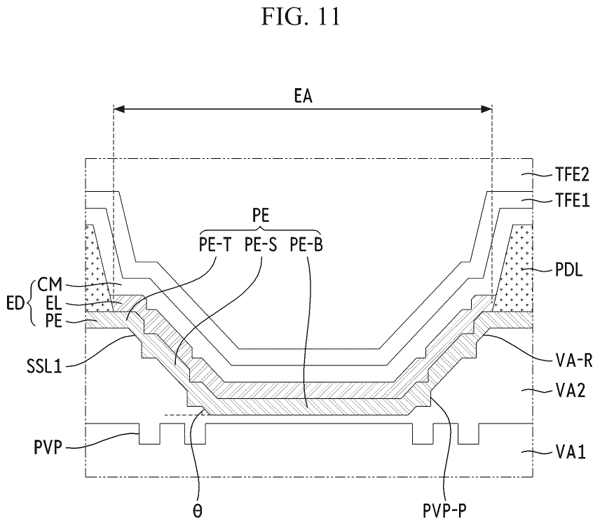

FIG. 11 is an enlarged view of a via layer and a light emitting element in the light emitting area of one or more embodiments of present disclosure.

The embodiments of FIG. 11 differ from one or more embodiments of FIG. 8 in that the uneven pattern PVP of the protective layers VA1 and VA2 and the uneven pattern PVP-P of the pixel electrode PVP are formed only in a portion of the light emitting area EA. In one or more embodiments of FIG. 11, the description overlapping with the embodiments of FIG. 8 will not be provided for conciseness.

Referring to FIG. 11, the uneven pattern PVP is formed only in an area overlapping the sloped surface SSL1 of the second protective layer VA2 in the thickness direction. Accordingly, an uneven pattern is formed on the sloped portion PE-S of the pixel electrode PE arranged on the sloped surface SSL1 of the second protective layer VA2. In contrast, the uneven pattern PVP is not formed on the bottom surface of the recess VA-R of the second protective layer VA2. Therefore, the uneven pattern PVP-P may not be formed on the bottom portion PE-B of the pixel electrode PE arranged on the bottom surface of the recess VA-R.

As such, because the light emitted laterally from the organic light emitting layer EL is effectively reflected, the luminance (brightness) ratio LvA by angle compared to the normal angle may be increased, and the luminance (brightness) ratio deviation dLvA may be reduced.

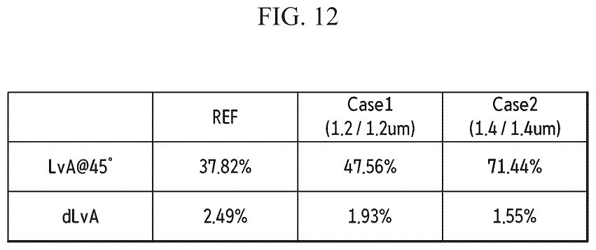

FIG. 12 is a table illustrating luminance ratio and luminance ratio deviation by angle relative to the square according to one or more embodiments of the present disclosure.

FIG. 12 illustrates a luminance ratio LvA and a luminance ratio deviation dLvA by angle for the display device according to one or more embodiments described with reference to FIGS. 5 to 8.

A display device in which the pixel electrode PE does not have a protrusion pattern is the reference REF, and case 1, in which the width of the protrusions of the uneven pattern of the pixel electrode PE and the distance between the protrusions of the uneven pattern of the pixel electrode PE are 1.2 μm and 1.2 μm, respectively, and case 2, in which the width of the protrusions of the uneven pattern of the pixel electrode PE and the distance between the protrusions of the uneven pattern of the pixel electrode PE are 1.4 μm and 1.4 μm, respectively, are compared.

Referring to FIG. 12, in the case of the reference example, the luminance ratio LvA by angle (45 degrees) relative to the normal is 37.82% and the luminance ratio deviation dLvA is 2.49%.

In case 1, the luminance ratio LvA by angle (45 degrees) relative to the normal is 47.56% and the luminance ratio deviation dLvA is 1.93%.

In case 2, the luminance ratio LvA by angle (45 degrees) relative to the normal is 71.44% and the luminance ratio deviation dLvA is 1.55%.

In this way, the embodiments of case 1 and case 2, which have an uneven pattern compared to the reference REF, the luminance ratio LvA by angle is higher and the luminance ratio deviation dLvA is lower when the pixel electrode PE does not have an uneven pattern.

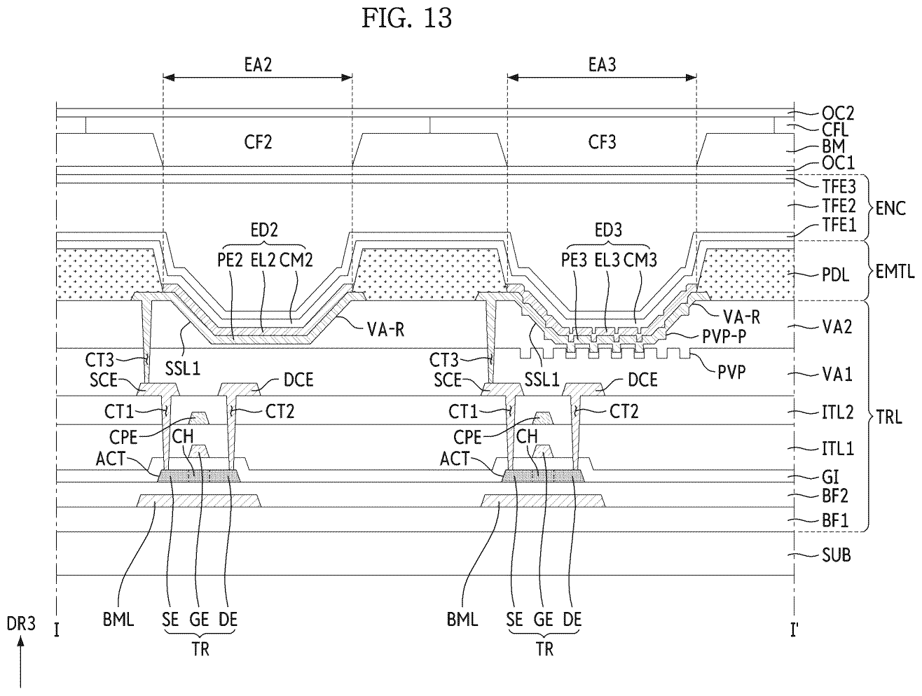

FIG. 13 is a cross-sectional view illustrating a display device including light emitting areas that emit light of different wavelengths according to one or more embodiments of the present disclosure. FIG. 13 illustrates a cross-section across the second light emitting area EA2 and the third light emitting area EA3 according to one or more embodiments.

In addition to FIGS. 5 to 8, a cross-sectional structure of the display device 10 will be described with reference to FIG. 13.

Referring to FIG. 13, the second light emitting area EA2 and the third light emitting area EA3 may be to emit light of different wavelengths. For example, the second light emitting area EA2 and the third light emitting area EA3 may be respectively to emit red light and green light, or green light and red light, or blue light and green light, or green light and blue light. However, embodiments of the present disclosure are not limited thereto.

The second light emitting area EA2 may include a second light emitting element ED2, and the third light emitting area EA3 may include a third light emitting element ED3.

The light emitting elements included in different light emitting areas may have different structures. For example, as described with reference to FIGS. 5 to 8, in one or more embodiments, the third light emitting area EA3 may include a third pixel electrode PE3 with an uneven pattern PVP-P.

The second light emitting element ED2 may include a second pixel electrode PE2, a second pixel light emitting layer EL2, and a common electrode CM2.

The second pixel electrode PE2 may be arranged to overlap one of the recesses VA-R defined by the second protective layer VA2. The second pixel electrode PE2 is arranged along a sloped surface SSL1 of the second protective layer VA2. Therefore, the second pixel electrode PE2 may have an inclined structure. The second pixel electrode PE2 may include a sloped portion arranged on the sloped surface SSL1 of the recess VA-R of the second protective layer VA2, a bottom portion connected to a lower portion of the sloped portion, and a top portion connected to a top portion of the sloped portion and arranged on a top portion of the second protective layer VA2. The inclination angle of the sloped portion of the second pixel electrode PE2 may be equal to the inclination angle of the sloped surface SSL1 of the second protective layer VA2. For example, in one or more embodiments, the inclination angle of the sloped portion may be 20 degrees to 70 degrees. The larger the inclination angle, the narrower the viewing angle, and the smaller the inclination angle, the better the luminance. The second pixel electrode PE2 may have a concave shape.

The second pixel light emitting layer EL2 may be arranged on the second pixel electrode PE2. Because the second pixel light emitting layer EL2 is formed along the second pixel electrode PE2 on the second pixel electrode PE2, it may have an inclined structure.

The second pixel light emitting layer EL2 may be an organic light emitting layer made of an organic material. When the second pixel light emitting layer EL2 corresponds to an organic light emitting layer, if (e.g., when) a thin film transistor applies a set or predetermined voltage to the second pixel electrode PE2 of the second light emitting element ED2, and the common electrode CE2 of the second light emitting element ED2 receives the common voltage or the cathode voltage, light may be emitted from the second pixel light emitting layer EL2.

The common electrode CE2 may be arranged on the second pixel light emitting layer EL2 in the second light emitting area EA2 and may be arranged on the pixel definition layer PDL.

The third light emitting element ED3 may include a third pixel electrode PE3, a third light emitting layer EL3, and a common electrode CE3.

The third light emitting area EA3 may include the third light emitting element ED3.

The light emitting elements included in different light emitting areas may have different structures. For example, as described with reference to FIGS. 5 to 8, the third pixel electrode PE3 of the third light emitting area EA3 may include an uneven pattern PVP-P.

In the third light emitting area EA3, the first protective layer VA1 may include an uneven pattern PVP formed in an area overlapping the light emitting area EA3 in the thickness direction (third direction DR3). A depth h1 of the uneven pattern PVP may be about 0.5 μm to about 1.0 μm. A width w1 of the uneven pattern may be about 1.0 μm to about 2.0 μm, and an interval w2 of the uneven pattern may be formed to be about 1.0 μm to about 2.0 μm. In one or more embodiments, the width w1 of the uneven pattern PVP and the interval w2 of the uneven pattern PVP may be the same, but embodiments of the present disclosure are not limited thereto.

The second protective layer VA2 may be arranged on the first protective layer VA1 including the uneven pattern PVP. For example, the second protective layer VA2 may be arranged on a front surface of the substrate SUB. The second protective layer VA2 may be made of a same material as the first interlayer insulating layer ITL1. The second protective layer VA2 may define the recess VA-R. The recess VA-R may overlap with the light emitting areas. The upper opening OP of the recess VA-R may be smaller than the light emitting area defined by the pixel definition layer PDL.

A depth of the recess VA-R may be smaller than a thickness of the second protective layer VA2.

A bottom surface of the second protective layer VA2 is formed with an uneven pattern according to the uneven pattern of the first protective layer VA1. The uneven pattern of the second protective layer VA2 may have a shape similar to the uneven pattern of the first protective layer VA1.

On the second protective layer VA2, the light emitting element layer EMTL including a light emitting element ED and the pixel definition layer PDL may be arranged.

In one or more embodiments, the third light emitting element ED3 may include a third pixel electrode PE3, a third organic light emitting layer EL3, and a common electrode CM3. The light emitting area EA3 represents an area in which the third pixel electrode PE3, the third organic light emitting layer EL3, and the common electrode CM3 are sequentially laminated, and holes from the third pixel electrode PE3 and electrons from the common electrode CM3 are combined with each other in the third organic light emitting layer EL3 to emit light. In these embodiments, the third pixel electrode PE3 may be an anode electrode of the third light emitting element ED3, and the common electrode CM3 may be a cathode electrode of the light emitting element ED3.

The third pixel electrode PE3 may be arranged to overlap a recess VA-R defined by the second protective layer VA2. The third pixel electrode PE3 is arranged along a sloped surface SSL1 of the recess VA-R. Therefore, the third pixel electrode PE3 may have an inclined structure. With reference to FIG. 8 and FIG. 13, the third pixel electrode PE3 may include an sloped portion PE-S arranged on the sloped surface SSL1 of the recess VA-R, a bottom portion PE-B connected to a bottom portion of the sloped portion PE-S, and a top portion PE-T connected to a top portion of the sloped portion PE-S and arranged on a top portion of the second protective layer VA2. An inclination angle of the sloped portion PE-S of the third pixel electrode PE3 may be the same as an inclination angle θ of the sloped surface SSL1 of the recess VA-R. For example, the inclination angle θ of the recess VA-R may be 20 degrees to 70 degrees. As the inclination angle θ increases, a viewing angle may narrow, and as the inclination angle θ decreases, brightness may improve. The third pixel electrode PE3 may have a concave shape. The sloped portion PE-S surrounds the bottom portion PE-B, and the sloped portion PE-S and the bottom portion PE-B do not overlap vertically. The bottom portion PE-B and the top portion PE-T may be substantially flat (e.g., relatively flat) but may be formed to have a curvature in the process. Even if (e.g., when) the bottom portion PE-B and the top portion PE-T have a curvature in the process, they may be formed to be relatively flat compared to the sloped portion PE-S.

The third pixel electrode PE3 has uneven pattern PVP-P formed in the light emitting area EA3 according to the uneven pattern PVP of the protective layers VA1 and VA2. For example, an uneven pattern PVP-P derived from the uneven pattern PVP of the protective layers VA1 and VA2 is formed in the sloped portion PE-S and the bottom portion PE-B of the third pixel electrode PE3. Accordingly, the uneven pattern PVP-P derived from the uneven pattern PVP of the protective layer VA1 and VA2 in the sloped portion PE-S and the bottom portion PE-B may have a shape substantially similar to the uneven pattern PVP or at least a portion of the uneven pattern PVP of the protective layers VA1 and VA2. In the case of the uneven pattern PVP-P of the sloped portion PE-S, although it is derived from the uneven pattern PVP of the protective layers VA1 and VA2, it may have a shape that is partially different from the uneven pattern PVP of the protective layers VA1 and VA2 due to the incline.

The light emitted from the third organic light emitting layer EL3 may be effectively reflected due to the uneven pattern PVP-P of the sloped portion PE-S and the bottom portion PE-B of the third pixel electrode PE3. In particular, because the light emitted laterally from the third organic light emitting layer EL3 is effectively reflected, the luminance (brightness) ratio LvA by angle may be increased compared to the normal angle, and the luminance (brightness) ratio deviation dLvA by angle may be reduced.

A first overcoat layer OC1 may be arranged on the encapsulation layer ENC.

A color filter layer CFL and a light blocking pattern BM may be arranged on the first overcoat layer OC1.

color filters CF2 and CF3 included in the color filter layer CFL may be respectively arranged in light emitting areas EA2 and EA3. The color filters CF2 and CF3 may include a second color filter CF2 and a third color filter CF3. The color filters CF2 and CF3 may each independently include a colorant, such as a dye and/or a pigment, that absorbs light of a wavelength other than light of a specific wavelength and may be arranged in response to the color of light emitted from the light emitting areas EA2 and EA3.

For example, in one or more embodiments, the second color filter CF2 may be arranged to overlap the second light emitting area EA2 and may be a red color filter that transmits only red second light. The third color filter CF3 may be arranged to overlap the third light emitting area EA3 and may be a green color filter that transmits only green third light.

The light blocking pattern BM may include a light absorbing material. For example, the light blocking pattern BM may include an inorganic black pigment and/or an organic black pigment. The inorganic black pigment may be Carbon Black, and the organic black pigment may include at least one of Lactam Black, Perylene Black, or Aniline Black, but embodiments of the present disclosure are not limited thereto. The light blocking pattern BM may improve the color reproducibility of the display device 10 by preventing or reducing visible light from interfering with and mixing colors between the light emitting areas EA2 and EA3.

A second overcoat layer OC2 may be arranged on the color filter layer CFL and the light blocking pattern BM.

The second overcoat layer OC2 may be arranged on the color filter layer CFL. The second overcoat layer OC2 may be a colorless, light transmission layer that does not have a color in the visible light band. For example, in one or more embodiments, the second overcoat layer OC2 may include a colorless, light transmitting organic material such as an acrylic resin.

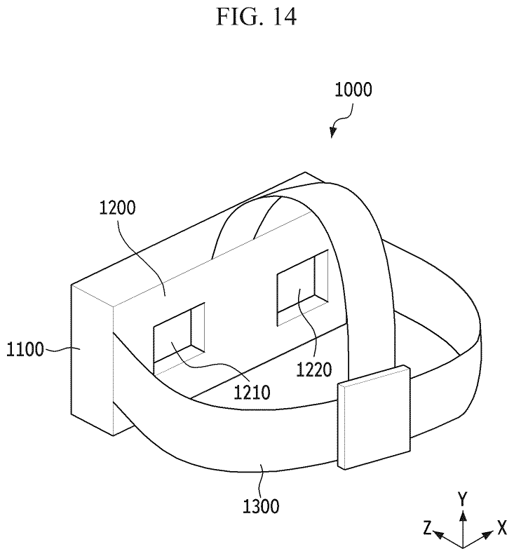

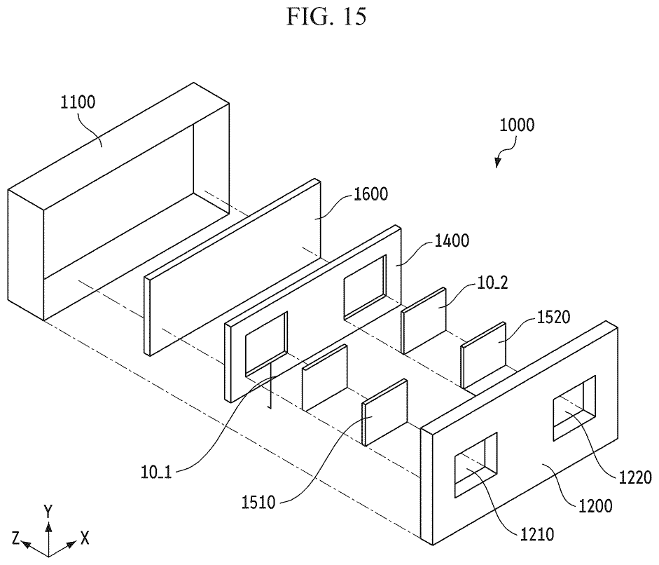

FIG. 14 is a perspective view illustrating an example of a head mounted display according to one or more embodiments of the present disclosure. FIG. 15 is an exploded perspective view illustrating the head mounted display device of FIG. 14 according to one or more embodiments.

Referring to FIG. 14 and FIG. 15, a head mounted display 1000 according to one or more embodiments includes a first display device 10_1, a second display device 10_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_1 provides an image to a user's left eye, and the second display device 10_2 provides an image to a user's right eye. Because each of the first display device 10_1 and the second display device 10_2 is substantially the same as the display device 10 described in conjunction with FIGS. 1 to 8, descriptions of the first display device 10_1 and the second display device 10_2 will not be provided for conciseness.

The first optical member 1510 may be arranged between the first display device 10_1 and the first eyepiece 1210. The second optical member 1520 may be arranged between the second display device 10_2 and the second eyepiece 1220. Each of the first optical member 1510 and the second optical member 1520 may include at least one convex lens.

The middle frame 1400 may be arranged between the first display device 10_1 and the control circuit board 1600 and between the second display device 10_2 and the control circuit board 1600. The middle frame 1400 serves to support and fix the first display device 10_1, the second display device 10_2, and the control circuit board 1600.

The control circuit board 1600 may be arranged between the middle frame 1400 and the display device housing 1100. The control circuit board 1600 may be connected to the first display device 10_1 and the second display device 10_2 through a connector. The control circuit board 1600 may convert an image source inputted from the outside into digital video data DATA, and transmit the digital video data DATA to the first display device 10_1 and the second display device 10_2 through the connector.

In one or more embodiments, the control circuit board 1600 may be to transmit the digital video data DATA corresponding to a left-eye image improved or optimized for the user's left eye to the first display device 10_1, and may be to transmit the digital video data DATA corresponding to a right-eye image improved or optimized for the user's right eye to the second display device 10_2. In one or more embodiments, the control circuit board 1600 may be to transmit the same digital video data DATA to the first display device 10_1 and the second display device 10_2.

The display device housing 1100 serves to accommodate the first display device 10_1, the second display device 10_2, the middle frame 1400, the first optical member 1510, the second optical member 1520, and the control circuit board 1600. The housing cover 1200 is arranged to cover one open surface of the display device housing 1100. The housing cover 1200 may include the first eyepiece 1210 at which the user's left eye looks and the second eyepiece 1220 at which the user's right eye looks. FIG. 9 and FIG. 10 illustrate that the first eyepiece 1210 and the second eyepiece 1220 are arranged separately, but embodiments of the present disclosure are not limited thereto. In one or more embodiments, the first eyepiece 1210 and the second eyepiece 1220 may be combined into one.

The first eyepiece 1210 may be aligned with the first display device 10_1 and the first optical member 1510, and the second eyepiece 1220 may be aligned with the second display device 10_2 and the second optical member 1520. Therefore, a user may view, through the first eyepiece 1210, an image of the first display device 10_1 magnified as a virtual image by the first optical member 1510, and may view, through the second eyepiece 1220, an image of the second display device 10_2 magnified as a virtual image by the second optical member 1520.

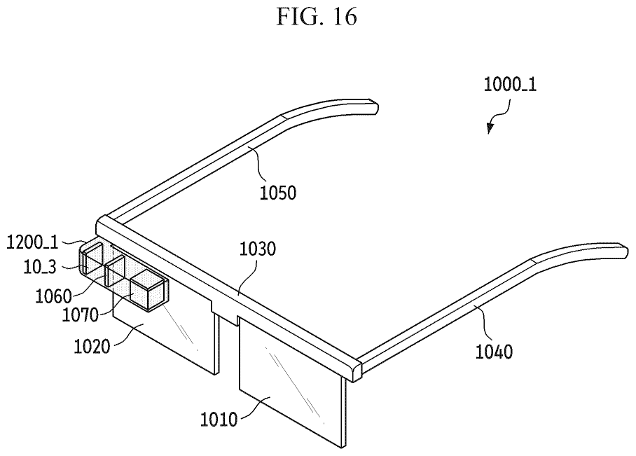

The head mounted band 1300 serves to secure the display device housing 1100 to a user's head such that the first eyepiece 1210 and the second eyepiece 1220 of the housing cover 1200 remain aligned with the user's left and right eyes, respectively. In one or more embodiments, when the display device housing 1200 is implemented to be lightweight and compact, the head mounted display 1000 may be provided with an eyeglass frame as shown in FIG. 16 instead of the head mounted band 1300.

FIG. 16 is a perspective view showing an example of a head mounted display device according to one or more embodiments of the present disclosure.

Referring to FIG. 16, a head mounted display 1000_1 according to one or more embodiments may be an eyeglasses-type (kind) display device in which a display device housing 1200_1 is implemented in a lightweight and compact manner. The head mounted display 1000_1 according to one or more embodiments may include a display device 10_3, a left eye lens 1010, a right eye lens 1020, a support frame 1030, temples 1040 and 1050, an optical member 1060, an optical path changing member 1070, and the display device housing 1200_1.

The display device housing 1200_1 may include the display device 10_3, the optical member 1060, and the optical path changing member 1070. An image displayed on the display device 10_3 may be magnified by the optical member 1060, and may be provided to the user's right eye through the right eye lens 1020 after the optical path thereof is changed by the optical path changing member 1070. As a result, the user may view an augmented reality image, through the right eye, in which a virtual image displayed on the display device 10_3 and a real image seen through the right eye lens 1020 are combined.

FIG. 16 illustrates that the display device housing 1200_1 is arranged at the right end of the support frame 1030, but embodiments of the present disclosure are not limited thereto. For example, in one or more embodiments, the display device housing 1200_1 may be arranged at the left end of the support frame 1030, and in these embodiments, the image of the display device 10_3 may be provided to the user's left eye. In one or more embodiments, the display device housing 1200_1 may be arranged at both (e.g., simultaneously) the left and right ends of the support frame 1030, and in these embodiments, the user may view the image displayed on the display device 10_3 through both (e.g., simultaneously) the left and right eyes.

A person of ordinary skill in the art would appreciate, in view of the present disclosure in its entirety, that each suitable feature of the various embodiments of the present disclosure may be combined or combined with one other, partially or entirely, and may be technically interlocked and operated in various suitable ways, and each embodiment may be implemented independently of one other or in conjunction with one other in any suitable manner unless otherwise stated or implied.

It should be understood, however, that the aspects and features of embodiments of the present disclosure are not restricted to the one set forth herein. The above and other aspects of the present disclosure will become more apparent to one of ordinary skill in the art to which the present disclosure pertains by referencing the claims, with equivalents thereof to be included therein. It is further understood that the scope of the present disclosure is defined by the appended claims and equivalents thereof rather than the detailed description described above, and all modifications and alterations derived from the claims and their equivalents fall within the scope of the present disclosure.

What is claimed is:

1. A display device comprising:
a substrate;
a thin film transistor on the substrate;
a planarization layer on the thin film transistor;
a protective layer on the planarization layer and having a plurality of recesses;
a first electrode arranged corresponding to each of the plurality of recesses on the protective layer;
a pixel definition layer defining a light emitting area and a non-light emitting area on the protective layer;
an organic light emitting layer on the first electrode in the light emitting area; and
a second electrode on the pixel definition layer and the organic light emitting layer,
wherein the first electrode comprises a sloped portion on a sloped surface of the recess and a bottom portion at a lower end of the sloped portion, and
wherein the sloped portion has a concave or convex pattern of unevenness.

2. The display device of claim 1, wherein the bottom portion has a concave or convex pattern of unevenness.

3. The display device of claim 2, wherein the protective layer has an uneven pattern on the sloped portion and the bottom portion.

4. The display device of claim 3,
wherein a depth of an unevenness of the uneven pattern of the protective layer is about 0.5 μm to about 1.0 μm,
wherein a width of the unevenness of the uneven pattern of the protective layer is about 1.0 μm to about 2.0 μm, and
wherein a distance between the unevenness of the uneven pattern of the protective layer is about 1.0 μm to about 2.0 μm.

5. The display device of claim 3,
wherein the protective layer comprises a first protective layer and a second protective layer on a top surface of the first protective layer, and
wherein the uneven pattern of the protective layer is on a top surface of the first protective layer and a bottom surface of the second protective layer.

6. The display device of claim 1,
wherein the organic light emitting layer is on the sloped portion and the bottom portion of the first electrode, and
wherein the organic light emitting layer comprises an uneven pattern corresponding to an uneven pattern of the first electrode.

7. The display device of claim 1,
wherein a depth of the recess is smaller than a thickness of the protective layer, and
wherein the sloped surface of the recess has an inclination angle in a range of 20° to 70°.

8. The display device of claim 7, wherein the sloped portion of the first electrode has substantially a same inclination angle as the sloped surface of the recess.

9. The display device of claim 1,
wherein the pixel definition layer does not overlap the sloped portion.

10. The display device of claim 9,
wherein the first electrode further comprises a top portion on an upper end of the sloped portion, and
wherein the pixel definition layer covers at least a portion of the top portion.

11. A display device comprising:
a substrate comprising a first light emitting area and a second light emitting area;
a thin film transistor on the substrate;
a planarization layer on the thin film transistor;
a protective layer on the planarization layer and having a first recess and a second recess, respectively overlapping the first light emitting area and the second light emitting area;
a first pixel electrode on the protective layer corresponding to the first recess and a second pixel electrode on the protective layer corresponding to the second recess;
an organic light emitting layer comprising a first pixel light emitting layer on the first pixel electrode of the first light emitting area and a second pixel light emitting layer on the second pixel electrode of the second light emitting area;
a pixel definition layer defining light emitting areas and non-light emitting areas on the protective layer; and
a common electrode on the pixel definition layer and the organic light emitting layer,
wherein the second pixel electrode comprises a sloped portion on a sloped surface of the second recess and a bottom portion at a lower end of the sloped portion, and
wherein the sloped portion and the bottom portion have a concave or convex pattern of unevenness.

12. The display device of claim 11,
wherein the first pixel electrode comprises a sloped portion on a sloped surface of the first recess and a bottom portion at a lower end of the sloped portion of the first pixel electrode, and
wherein the first pixel electrode does not comprise an uneven portion.

13. The display device of claim 12,
wherein the protective layer has an uneven pattern below the uneven pattern of the sloped portion and the bottom portion of the second pixel electrode.

14. The display device of claim 13,
wherein a depth of an unevenness of the uneven pattern of the protective layer is about 0.5 μm to about 1.0 μm,
wherein a width of the unevenness of the uneven pattern of the protective layer is about 1.0 μm to about 2.0 μm, and
wherein a distance between the unevenness of the uneven pattern of the protective layer is about 1.0 μm to about 2.0 μm.

15. The display device of claim 13,
wherein the protective layer comprises a first protective layer and a second protective layer on a top surface of the first protective layer, and
wherein the uneven pattern of the protective layer is on a top surface of the first protective layer and a bottom surface of the second protective layer.

16. The display device of claim 11,
wherein the organic light emitting layer is on the sloped portion and the bottom portion of each of the first pixel electrode and the second pixel electrode, and
wherein the organic light emitting layer comprises an uneven pattern corresponding to an uneven pattern of the second pixel electrode.

17. The display device of claim 11,
wherein a depth of each of the first recess and the second recess is smaller than a thickness of the protective layer,
wherein a sloped surface of the first recess has an inclination angle in a range of 20° to 70°, and
wherein the sloped surface of the second recess has an inclination angle in a range of 20° to 70°.

18. The display device of claim 17,
wherein a sloped portion of the first pixel electrode has substantially a same inclination angle as a sloped surface of the first recess, and
wherein a sloped portion of the second pixel electrode has substantially a same inclination angle as the sloped surface of the second recess.

19. The display device of claim 11, further comprising
a thin film encapsulation layer on the common electrode and comprising a first inorganic film layer, a second inorganic film layer, and an organic film layer between the first inorganic film layer and the second inorganic film layer;
a color filter layer on the thin film encapsulation layer; and
an overcoat layer between the thin film encapsulation layer and the color filter layer,
wherein the color filter layer comprises a first color filter overlapping the first light emitting area and a second color filter overlapping the second light emitting area,
wherein the first color filter is one of a blue color filter to transmit blue light or a red color filter to transmit red light, and
wherein the second color filter is a green color filter to transmit green light.

20. An electronic device comprising a display panel;
the display panel comprises,
a substrate;
a thin film transistor on the substrate;
a planarization layer on the thin film transistor;
a protective layer on the planarization layer and having a plurality of recesses;
a first electrode arranged corresponding to each of the plurality of recesses on the protective layer;
a pixel definition layer defining a light emitting area and a non-light emitting area on the protective layer;
an organic light emitting layer on the first electrode in the light emitting area; and
a second electrode on the pixel definition layer and the organic light emitting layer,
wherein the first electrode comprises a sloped portion on a sloped surface of the recess and a bottom portion at a lower end of the sloped portion, and
wherein the sloped portion has a concave or convex pattern of unevenness.
